(19) United States
(12) Patent Application Publication
(10) Pub. No.: US 2023/0209976 A1
(43) Pub. Date: Jun. 29, 2023

(54) LIGHT EMITTING DISPLAY DEVICE

(71) Applicant: LG DISPLAY CO., LTD., SEOUL (KR)

(72) Inventors: Dongik KIM, Gyeonggi-do (KR); HeeSuk PANG, Gyeonggi-do (KR); Insu HWANG, Seoul (KR); Hyoung-Su KIM, Seoul (KR)

(73) Assignee: LG DISPLAY CO., LTD., SEOUL (KR)

(21) Appl. No.: 18/087,862

(22) Filed: Dec. 23, 2022

(30) Foreign Application Priority Data
Dec. 28, 2021 (KR) 10-2021-0189820
Nov. 29, 2022 (KR) 10-2022-0162572

(51) Int. Cl. H10K 59/80; H10K 59/122; H10K 59/131; H10K 59/121

(52) U.S. Cl. CPC H10K 59/8794; H10K 59/122; H10K 59/873; H10K 59/131; H10K 59/1213

(57) ABSTRACT

A light emitting display device can prevent degradation of the light emitting elements in the display area due to moisture and oxygen and enhance the reliability of the light emitting display panel by placing a structure capable of delaying penetration of moisture and oxygen into the display area on the periphery of the light emitting display panel.

### CROSS-REFERENCE TO RELATED APPLICATION

This application claims the priorities of Korean Patent Application No. 10-2021-0189820, filed on Dec. 28, 2021, and Korean Patent Application No. 10-2022-0162572, filed on Nov. 29, 2022, which are hereby incorporated by reference in their entirety for all purposes as if fully set forth herein.

### BACKGROUND

### Field of the Present Disclosure

The present disclosure relates to light emitting display devices.

### Description of the Background

A light emitting display device is a display device that outputs light by means of light emitting elements and includes a light emitting display panel provided with light emitting elements.

The light emitting elements are covered by an encapsulation substrate. The encapsulation substrate is attached to the top of the light emitting elements through an encapsulation layer.

The light emitting layer constituting the light emitting elements may be provided on the entire surface of the light emitting display panel, and the side surface of the light emitting layer is covered by the encapsulation layer.

However, moisture and oxygen can penetrate into the light emitting layer through the side surface of the light emitting layer provided outside the light emitting display panel, so that the light emitting elements can be degraded.

### SUMMARY

Accordingly, the present disclosure is to provide a light emitting display device that can restrain or delay penetration into the display area of the moisture and oxygen, introduced through the side surface of the light emitting layer on the outermost periphery of the light emitting display panel by placing a structure, which is capable of delaying penetration of moisture and oxygen into the display area on the periphery of the light emitting display panel.

Various aspects of the present disclosure may provide a light emitting display device that may prevent or reduce degradation of the light emitting elements in the display area due to moisture and oxygen and enhance the reliability of the light emitting display panel by providing a foreign matter blocking area as a structure capable of delaying penetration of moisture and oxygen into the display area on the periphery of the light emitting display panel.

Various aspects of the present disclosure may provide a light emitting display device that may prevent or reduce degradation of the light emitting elements in the display area due to moisture and oxygen and enhance the reliability of the light emitting display panel by providing an undercut area as a structure capable of delaying penetration of moisture and oxygen into the display area on the periphery of the light emitting display panel.

Various aspects of the present disclosure may provide a light emitting display device that may prevent or reduce degradation of the light emitting elements in the display area due to moisture and oxygen and enhance the reliability of the light emitting display panel by providing a pixel undercut area as a structure capable of delaying penetration of moisture and oxygen into the display area on the periphery of the light emitting display panel.

Various aspects of the present disclosure provide a light emitting display device comprising a substrate divided into a display area and a non-display area surrounding the display area, a pixel driving circuit layer provided on the substrate and including a driving transistor, a planarization layer covering the pixel driving circuit layer, anode electrodes provided on the planarization layer and respectively provided in pixels, banks disposed between the anode electrodes, a light emitting layer disposed on the anode electrodes and the banks, a cathode electrode disposed on the light emitting layer, a capping layer covering the cathode electrode, an encapsulation layer provided on side surfaces and an upper surface of the capping layer, and an encapsulation substrate attached to an upper end of the capping layer through the encapsulation layer.

Various aspects of the present disclosure may provide the light emitting display device, wherein the light emitting layer and the cathode electrode are provided in the display area and the non-display area, wherein the non-display area includes an area where the light emitting layer and the cathode electrode each are disconnected, and wherein the area where the light emitting layer and the cathode electrode each are disconnected includes a foreign matter blocking area where the pixel driving circuit layer is covered by the encapsulation layer and which surrounds the display area.

Various aspects of the present disclosure may provide the light emitting display device wherein an undercut area is provided along the foreign matter blocking area and wherein a side surface of the light emitting layer is covered by the cathode electrode.

Various aspects of the present disclosure may provide the light emitting display device wherein a foreign matter blocking area including an area where the light emitting layer and the cathode electrode each are disconnected is provided, and a pixel undercut area disposed in the non-display area along the foreign matter blocking area is provided.

According to various aspects of the present disclosure, there may be provided a light emitting display device that may prevent degradation of the light emitting elements in the display area due to moisture and oxygen and enhance the reliability of the light emitting display panel by placing a structure capable of delaying penetration of moisture and oxygen into the display area on the periphery of the light emitting display panel.

### BRIEF DESCRIPTION OF THE DRAWINGS

The above and other features and advantages of the present disclosure will be more clearly understood from the following detailed description, taken in conjunction with the accompanying drawings, in which:

FIG. 1 is an exemplary view illustrating a configuration of a light emitting display device according to aspects of the present disclosure;

FIG. 2 is an exemplary view illustrating a structure of a pixel applied to a light emitting display device according to aspects of the present disclosure;

FIG. 3 is an exemplary view illustrating a structure of a gate driver applied to a light emitting display device according to aspects of the present disclosure;

FIG. 4 is an exemplary view illustrating a configuration of stages constituting the gate driver of FIG. 3 according to aspects of the present disclosure;

FIG. 5 is a cross-sectional view schematically illustrating a light emitting display panel applied to a light emitting display device according to aspects of the present disclosure;

FIGS. 6A, 6B, and 6C are exemplary views illustrating a method for manufacturing the light emitting display panel of FIG. 5;

FIGS. 7, 8, and 9 are plan views illustrating a light emitting display panel applied to a light emitting display device according to aspects of the present disclosure;

FIGS. 10, 11, 12, 13, 14, and 15 are exemplary views illustrating a structure of a light emitting display panel applied to a light emitting display device according to aspects of the present disclosure;

FIGS. 16, 17A, 17B, 17C, 18A, 18B, 19A, 19B, 20A, 20B, and 20C are exemplary views illustrating the positions of a heat line and a main heat line in a light emitting display device according to aspects of the present disclosure;

FIG. 21 is a plan view illustrating a light emitting display panel applied to a light emitting display device according to aspects of the present disclosure;

FIGS. 22A and 22B each are enlarged exemplary views illustrating Y area and Z area of FIG. 21 according to aspects of the present disclosure;

FIGS. 23, 24, 25, 26, 27, 28, 29, and 30 are exemplary views illustrating an undercut structure provided in an undercut area in a light emitting display device according to aspects of the present disclosure; and

FIGS. 31 and 32 are exemplary views illustrating an undercut structure provided in a pixel undercut area in a light emitting display device according to aspects of the present disclosure.

### DETAILED DESCRIPTION

In the following description of examples or aspects of the present disclosure, reference will be made to the accompanying drawings in which it is shown by way of illustration specific examples or aspects that can be implemented, and in which the same reference numerals and signs can be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

In the following description of examples or aspects of the present disclosure, reference will be made to the accompanying drawings in which it is shown by way of illustration specific examples or aspects that can be implemented, and in which the same reference numerals and signs can be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various aspects of the present disclosure are described in detail with reference to the accompanying drawings.

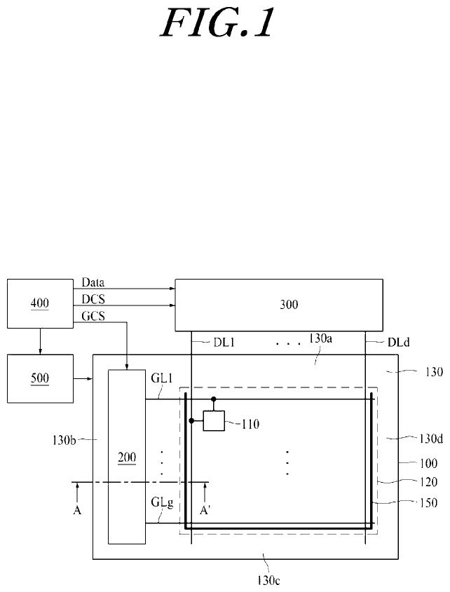

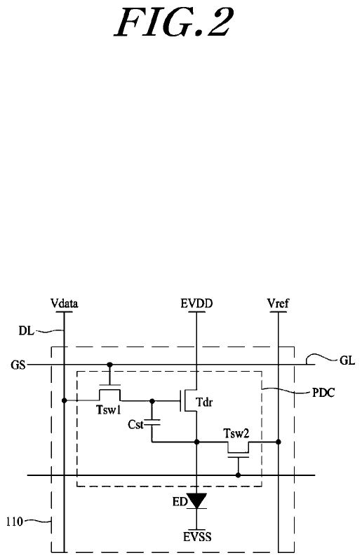

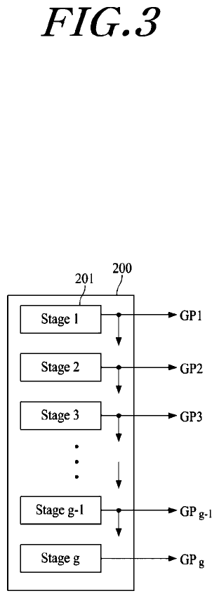

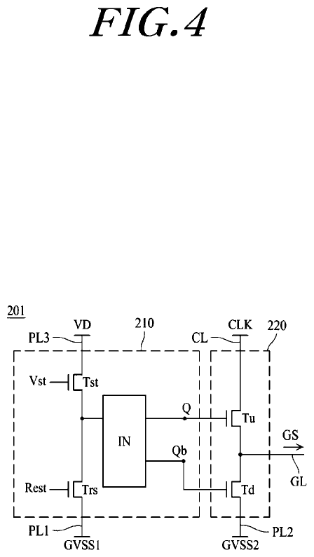

FIG. 1 is an exemplary view illustrating a configuration of a light emitting display device according to aspects of the present disclosure. FIG. 2 is an exemplary view illustrating a structure of a pixel applied to a light emitting display device according to aspects of the present disclosure, FIG. 3 is an exemplary view illustrating a structure of a gate driver applied to a light emitting display device according to aspects of the present disclosure. FIG. 4 is an exemplary view illustrating a configuration of stages constituting the gate driver of FIG. 3.

The light emitting display device according to aspects of the present disclosure may constitute various electronic devices. The electronic device may be, e.g., a smartphone, a tablet PC, a TV, or a monitor.

As shown in FIG. 1, a light emitting display device according to aspects of the present disclosure includes a light emitting display panel 100 including a display area 120 outputting an image and a non-display area 130 provided outside the display area, a gate driver 200 supplying gate signals to gate lines GL1 to GLg provided in the display area of the light emitting display panel, a data driver 300 supplying data voltages to data lines DL1 to DLd (d being a natural number greater than 1) provided on the light emitting display panel, a controller 400 controlling the driving of the gate driver 200 and the data driver 300, and a power supply unit 500 supplying power to the controller, the gate driver, the data driver, and the light emitting display panel.

The light emitting display panel 100 may include the display area 120 and the non-display area 130. The display area 120 includes the gate lines GL1 to GLg (g being a natural number greater than 1), the data lines DL1 to DLd, and pixels 110. Accordingly, images are output in the display area 120. The non-display area 130 surrounds the display area 120. The non-display area 130 includes a first non-display area 130a including the data driver 300, a second non-display area 130b including the gate driver 200, a third non-display area 130c facing the first non-display area 130a, and a fourth non-display area 130d facing the second non-display area 130b.

The data driver 300 may be provided on a chip-on film attached to the light emitting display panel 100 or may be provided on the main substrate on which the controller 400 is provided. The data driver 300 attached to the chip-on-film may be electrically connected to data line pads provided in the first non-display area 130a. The data driver provided on the main substrate may also be electrically connected to the data line pads provided in the first non-display area 130a. The data driver 300 may be directly connected to the data line pads provided in the first non-display area 130a. The data line pads are connected to the data lines DL1 to DLd.

The gate driver 200 may be directly embedded in the second non-display area 130b by a gate in panel (GIP) scheme. In this case, the transistors constituting the gate driver 200 may be provided in the second non-display area 130b through the same process as the transistors respectively disposed in the pixels 110 of the display area 120. A gate driver may also be provided in the fourth non-display area 130d facing the second non-display area 130b, by the gate-in-panel scheme.

When the gate pulse generated by the gate driver 200 is supplied to the gate of the switching transistor Tsw1 provided in the pixel 110, the switching transistor is turned on. As the switching transistor is turned on, the data voltage supplied through the data line may be applied to the gate of the driving transistor Tdr. When a gate-off signal is supplied to the switching transistor Tsw1, the switching transistor is turned off. The gate signal GS supplied to the gate line GL may include the gate pulse and the gate-off signal.

As shown in FIG. 2, the pixel 110 disposed on the light emitting display panel 100 may include a light emitting element ED, a switching transistor Tsw1, a storage capacitor Cst, a driving transistor Tdr, and a sensing transistor Tsw2. A pixel driving circuit PDC may include the switching transistor Tsw1, the storage capacitor Cst, the driving transistor Tdr, and the sensing transistor Tsw2. The driving transistor Tdr and the light emitting element ED are connected between a high-potential power source EVDD and a low-potential power source EVSS. One terminal of the sensing transistor Tsw2 is connected with a reference voltage Vref.

More specifically, the light emitting element ED includes an anode electrode, a cathode electrode, and a light emitting layer provided between the anode electrode and the cathode electrode.

The pixel 110 applied to the aspects of the present disclosure may have the structure as shown in FIG. 2, but aspects of the present disclosure are not limited thereto. Accordingly, the pixel applied to the aspects of the present disclosure may have various forms other than the structure shown in FIG. 2.

The gate driver 200 as shown in FIG. 1 includes stages 201 (Stage 1 to Stage g) as illustrated in FIG. 3. Each of the stages 201 may be connected to at least one gate line GL and outputs GP1 to GPg.

As illustrated in FIG. 4, each of the stages 201 includes a signal output unit 220 including a pull-up transistor Tu outputting the gate pulse GP (GP1 to GPg) and a pull-down transistor Td outputting the gate off signal and a signal generation unit 210 generating signals for driving the pull-up transistor Tu and the pull-down transistor Td.

The signal generation unit 210 may include a plurality of transistors. FIG. 4 illustrates a signal generation unit 210 including two transistors Tst and Trs and an inverter IN to describe the basic structure and basic functions of the signal generation unit 210 applied to the aspects of the present disclosure. In other words, FIG. 4 schematically illustrates an exemplary of the signal generation unit 210 applied to various aspects of the present disclosure.

The start transistor Tst is turned on by a start signal Vst to supply a high voltage VD to the signal output unit 220 through a Q node Q. The high voltage VD passing through the start transistor Tst may be converted into a low voltage by the inverter IN and be transmitted to a Qb node Qb.

If the start transistor Tst is turned off, and the reset transistor Trs is turned on by a reset signal Rest, a first low voltage GVSS1 may be supplied to the Q node Q through the reset transistor Trs. The first low voltage GVSS1 may be converted into the high voltage VD by the inverter IN and be supplied to the Qb node Qb. The inverter IN may be formed as various structures including at least one transistor.

In other words, to perform the functions described above, the signal generation unit 210 may include a basic structure as illustrated in FIG. 4, and the signal generation unit 210 may have different structures depending on its functions.

The signal output unit 220 outputs the gate pulse GS (or a gate off signal) depending on the signal transmitted from the signal generation unit 210.

As described above, the stage 201 includes a plurality of transistors, so that the gate driver 200 includes a plurality of transistors. The transistors constituting the gate driver 200 are provided in the second non-display area 130b shown in FIG. 1.

Power supply lines PL1, PL2, and PL3 and at least one clock line CL connected to the stages 201 may be provided in the second non-display area 130b. Gate driver power GVSS1, GVSS2, and the high voltage VD may be supplied to the stages through the power supply lines PL1, PL2, and PL3, and at least one gate clock CLK may be supplied to the stages through the at least one clock line CL.

In other words, the transistors, power supply lines PL1, PL2, and PL3, and at least one clock line CL are provided in the second non-display area 130b.

The controller 400 may include a data arranging unit for rearranging the input image data received from an external system using the timing sync signal received from the external system and supplying the rearranged image data Data to the data driver 300, a control signal generation unit for generating a gate control signal GCS and a data control signal DCS using the timing sync signal, an input unit for receiving the input image data received from the external system and the timing sync signal and transmitting the input image data to the data arranging unit and the control signal generation unit, and an output unit for outputting the image data Data generated by the data arranging unit and the control signals DCS and GCS generated by the control signal generation unit to the data driver 300 or the gate driver 200.

The gate control signal GCS may include at least one gate clock CLK.

The external system performs the function of driving the controller 400 and the electronic device. When the electronic device is a smartphone, the external system may receive various voice information, image information, and text information through a wireless communication network. The external system transmits the received image information to the controller 400. The image information may be input image data.

The power supply unit 500 generates various power and supplies the generated power to the controller 400, the gate driver 200, the data driver 300, and the light emitting display panel 100.

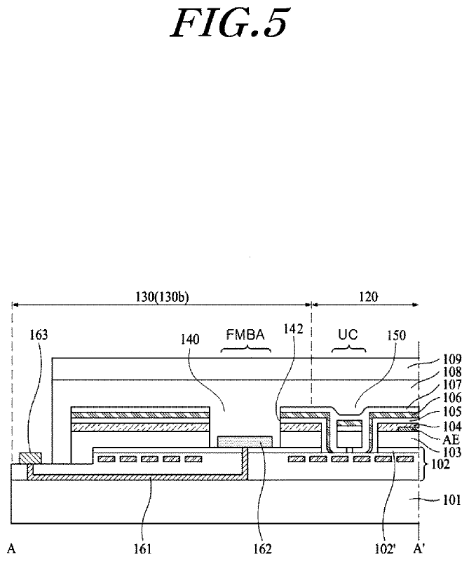

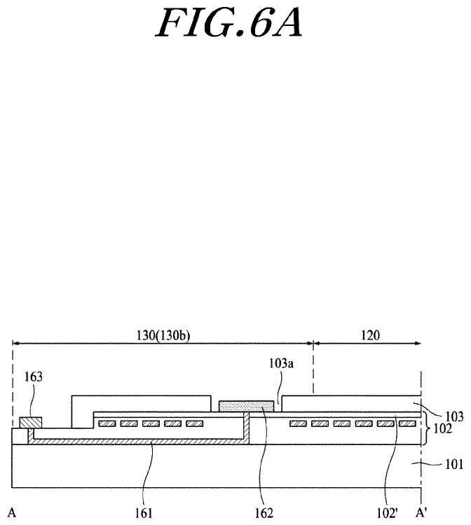

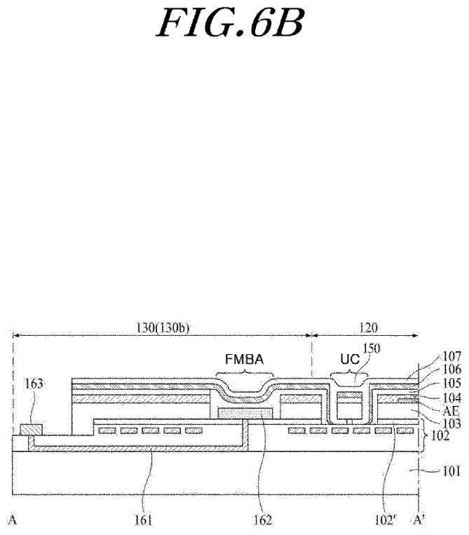

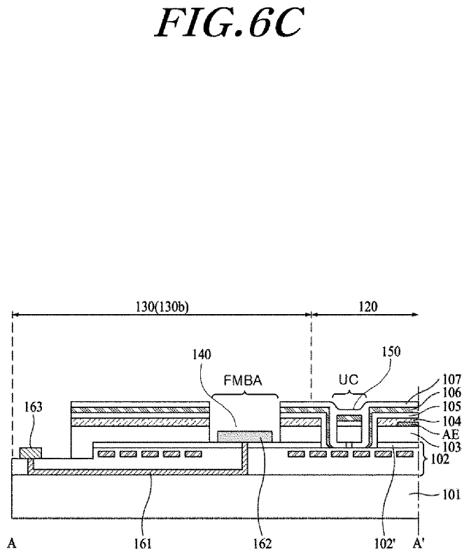

FIG. 5 is a cross-sectional view schematically illustrating a light emitting display panel applied to a light emitting display device according to aspects of the present disclosure. In other words, FIG. 5 is a view for describing features of the light emitting display device according to aspects of the present disclosure. FIG. 5 may be a cross-sectional view taken along line A-A′ of FIG. 1, for example. FIGS. 6A, 6B, and 6C are exemplary views illustrating a method for manufacturing the light emitting display panel of FIG. 5.

As illustrated in FIGS. 1 and 5, a light emitting display panel 100 applied to the light emitting display device according to aspects of the present disclosure includes a substrate 101 divided into a display area 120 and a non-display area 130 surrounding the display area 120, a pixel driving circuit layer 102 provided on the substrate and including a driving transistor Tdr, a planarization layer 103 covering the pixel driving circuit layer, anode electrodes AE provided on the planarization layer and respectively provided in pixels, banks 104 disposed between the anode electrodes, a light emitting layer 105 disposed on the anode electrodes and the banks, a cathode electrode 106 disposed on the light emitting layer, a capping layer 107 covering the cathode electrode, an encapsulation layer 108 provided on an upper surface and side surfaces of the capping layer, and an encapsulation substrate 109 attached to the top surface or upper end of the capping layer 107 through the encapsulation layer 108.

The light emitting display panel applied to the light emitting display device according to aspects of the present disclosure includes a structure capable of delaying penetration of moisture and oxygen from outside into the display area. The structure may be implemented in a foreign matter blocking area, an undercut area, and a pixel undercut area.

In this case, the light emitting layer 105 and the cathode electrode 106 are provided in the display area 120 and the non-display area 130, and the non-display area 130 has an area where the light emitting layer 105 and the cathode electrode 106 are disconnected. In the area where the light emitting layer 105 and the cathode electrode 106 are disconnected, the pixel driving circuit layer 102 is covered by the encapsulation layer 108, forming the foreign matter blocking area FMBA surrounding the display area 120.

A heat line 162 is provided in the foreign matter blocking area FMBA. A heat line hole 140 is provided in the light emitting layer 105 provided in the foreign matter blocking area FMBA, and the heat hole 140 surrounds the display area 120. The heat line 162 exposed through the heat line hole 140 is covered by the encapsulation layer 108.

In the following description, aspects of the present disclosure are described with reference to the second non-display area 130b where the gate driver 200 is provided, in the non-display area 130. When the gate driver 200 is also provided in the fourth non-display area 130d, the structure of the fourth non-display area 130d is the same as the structure of the second non-display area 130b. The third non-display area 130c may have the same structure as the structure of the second non-display area 130b except that it lacks the gate driver 200.

Accordingly, the following description may also be applied to the second non-display area 130b, the third non-display area 130c, and the fourth non-display area 130d.

In this case, a heat line 162 and a heat line hole 140 may be provided in the first non-display area 130a as well. In other words, since various signal lines including the data lines DL1 to DLd are provided in the first non-display area 130a, it may be difficult to provide a heat line and a heat line hole therein. However, if an area where a heat line and a heat line hole are to be provided may be secured between signal lines, the first non-display area 130a may also have a heat line 162 and a heat line hole 140. In this case, the heat line 162 and the heat line hole 140 may be provided to be continuous in the first non-display area 130a or may be partially provided. Accordingly, the following description may also be applied to the first non-display area 130a.

The substrate 101 may be a glass substrate or a plastic substrate or various types of films.

The pixel driving circuit layer 102 including the driving transistor Tdr is provided on an upper end of the substrate 101.

The pixel driving circuit PDC including the driving transistor Tdr is provided in the display area 120 of the pixel driving circuit layer 102. As described with reference to FIG. 2, the pixel driving circuit PDC may include a switching transistor Tsw1, a storage capacitor Cst, a driving transistor Tdr, and a sensing transistor Tsw2 and may be formed in various forms.

The transistors constituting the gate driver 200 may be provided in the non-display area 130 of the pixel driving circuit layer 102, e.g., the second non-display area 130b.

The pixel driving circuit layer 102 may include at least one insulation film and at least two metal layers. The insulation film may be formed of at least one inorganic film or at least one organic film or may be formed of at least one inorganic layer and at least one organic layer.

Since the characteristics of the aspects of the present disclosure do not lie in the structure of the pixel driving circuit layer 102, a detailed description of the pixel driving circuit layer 102 is omitted.

A planarization layer 103 is provided on an upper end of the pixel driving circuit layer 102. Since the planarization layer 103 covers the pixel driving circuit layer 102, the planarization layer 103 is provided in the display area 120 and the non-display area 130 as illustrated in FIG. 5.

For example, various types of transistors and signal lines forming the pixel driving circuit PDC and the gate driver 200 are provided on the pixel driving circuit layer 102. In this case, heights of various types of transistors and signal lines may be different. In the pixel driving circuit layer 102, the area in which the transistors and signal lines are provided and the area in which the transistors and signal lines are not provided may also have different heights.

Due to such a height difference, the top surface formed by the transistors and the signal lines may not be flat. Accordingly, the top surface of the pixel driving circuit layer 102 may not be flat.

The planarization layer 103 functions to planarize the top surface of the non-flat pixel driving circuit layer 102. Accordingly, the top surface of the planarization layer 103 may form a flat surface. The planarization layer 103 may be formed to have a height greater than that of the pixel driving circuit layer 102.

The planarization layer 103 may be formed of at least one organic layer, but is not limited thereto. For example, the planarization layer 103 may be formed of at least one inorganic layer and at least one organic layer.

The anode electrodes AE are provided on an upper end of the planarization layer 103. The anode electrode AE forms a light emitting element ED. The anode electrode AE may be electrically connected to the driving transistor Tdr disposed on the pixel driving circuit layer 102 and is patterned for each pixel.

The anode electrode AE may be one of two electrodes constituting the light emitting element ED. For example, when the light emitting element ED is an organic light emitting diode, the organic light emitting diode may include a first pixel electrode, a light emitting layer disposed on an upper end of the first pixel electrode, and a second pixel electrode disposed on an upper end of the light emitting layer. The first pixel electrode may be the anode electrode AE. The second pixel electrode may be the cathode electrode. In this case, the anode electrode AE is connected to the driving transistor Tdr.

The anode electrode AE may be formed of a transparent electrode, such as indium tin oxide (ITO) and indium zinc oxide (IZO). The anode electrode AE may be formed of an opaque electrode, such as copper (Cu). The anode electrode AE may be formed by stacking a transparent electrode and an opaque electrode.

The bank 104 covers the periphery of the anode electrode AE, and thus, an opening through which light is output from one pixel may be formed. In other words, the bank 104 is provided in the display area and the non-display area. An opening through which the anode electrode AE of each pixel is exposed may be formed in the bank 104 provided in the display area, and light may be output through the opening.

The bank 104 may be formed of at least one inorganic layer or at least one organic layer. The bank 104 may be formed by stacking at least one inorganic layer and at least one organic layer.

The light emitting layer 105 may be provided in the display area 120 and the non-display area 130 to cover the anode electrodes AE and the bank 104.

The light emitting layer 105 may include any one of an organic light emitting layer, an inorganic light emitting layer, and a quantum dot light emitting layer. The light emitting layer 105 may include a stacked or mixed structure of an organic light emitting layer (or an inorganic light emitting layer) and a quantum dot light emitting layer.

The light emitting layer 105 may include a hole injection layer HIL, a hole transport layer HTL, a hole blocking layer HBL, an electron injection layer EIL, an electron transport layer ETL, an electron blocking layer EBL, and a charge generation layer CGL.

The light emitting layer 105 may include layers stacked in various orders different than the above-described stacking order.

The light emitting layer 105 may be configured to output light having various colors, such as red, green, and blue. The light emitting layer 105 may be configured to output white light.

The cathode electrode 106 is provided on an upper end of the light emitting layer 105. The cathode electrode 106 may be provided in the display area 120 and the non-display area 130.

The cathode electrode 106 may be formed of a transparent metal, such as indium tin oxide (ITO) and indium zinc oxide (IZO) and may be formed of an opaque metal, such as copper and aluminum (Al).

For example, when the aspects of the present disclosure adopt a top emission scheme in which light is output to the outside through the cathode electrode 106, the cathode electrode 106 may be formed of a transparent metal, such as indium tin oxide (ITO) and indium zinc oxide (IZO), or be formed of a metal-mixed material including magnesium (Mg) and silver (Ag). In this case, the anode electrode AE may include a transparent electrode and a reflective electrode.

When the aspects of the present disclosure adopt a bottom emission design in which light is output to the outside through the anode electrode AE, the cathode electrode 106 may be formed of a material having a reflective characteristic, such as aluminum (Al), and the anode electrode AE may be formed of various types of transparent metals.

The aspects of the present disclosure may be applied to both light emitting display devices using the bottom emission scheme and light emitting display devices using the top emission scheme.

The capping layer 107 may be provided in the display area 120 and the non-display area 130 to cover the cathode electrode 106. The capping layer 107 may function to protect the cathode electrode 106.

The encapsulation layer 108 may be provided on side surfaces and an upper surface of the capping layer 107, and the encapsulation substrate 109 may be attached to the top of the capping layer 107 through the encapsulation layer.

The encapsulation layer 108 may cover side surfaces and upper surface of the capping layer 107, the cathode electrode 106, the light emitting layer 105, the bank 104, and the planarization layer 103 provided under the encapsulation layer 108 as illustrated in FIG. 5. Accordingly, the encapsulation layer 108 may perform an encapsulation function to block the components from the outside.

The encapsulation substrate 109 may be formed of at least one inorganic layer or at least one organic layer or be formed by stacking at least one inorganic layer and at least one organic layer or may be a metal encapsulation layer.

In this case, the encapsulation layer 108 and the encapsulation substrate 109 may include an adhesive layer FSP and a metal encapsulation layer FSM or may include an adhesive material FSA and a metal encapsulation layer FSM.

When the light emitting element outputs white light, a color filter may be further provided on an upper end of the planarization layer, inside the planarization layer, or on an upper end of the cathode electrode.

Hereinafter, a method for manufacturing a light emitting display device, in particular, the light emitting display panel 100 according to aspects of the present disclosure, is described with reference to FIGS. 5 to 6C.

A main heat line 161 connected to a heat line 162 is provided in the non-display area 130 of the substrate 101. The main heat line 161 may be provided on an upper end of the buffer provided on the substrate 101. The main heat line 161 may be provided in the second non-display area 130b, the third non-display area 130c, and the fourth non-display area 130d. However, as described above, when the heat line 162 is provided in the first non-display area 130a, the main heat line 161 may also be provided in the first non-display area 130a.

The pixel driving circuit layer 102 is provided in the display area 120 and the non-display area 130. Accordingly, the main heat line 161 is covered by the pixel driving circuit layer 102.

Next, the planarization layer 103 is provided in the display area 120 and the non-display area 130 to cover the pixel driving circuit layer 102. In particular, the pixel driving circuit layer 102 includes a protection layer 102′ covering the top of the transistors provided in the pixel driving circuit layer 102, and the protection layer 102′ is covered by the planarization layer.

As shown in FIG. 6A, the planarization layer 103 provided in the non-display area 130 is patterned, forming a planarization layer hole 103a.

The heat line 162 is provided in the planarization layer hole 103a, and the heat line 162 is connected to the main heat line 161 through a contact hole provided in the pixel driving circuit layer 102 or the pixel driving circuit layer 102 and the planarization layer 103. In other words, the planarization layer hole 103a may be a space where the heat line 162 is provided. In this case, the planarization layer hole 103a may be fully or partially filled with the heat line 162.

Since the heat line 162 is provided in the planarization layer hole 103a, the planarization layer hole 103a may be provided in the second non-display area 130b, the third non-display area 130c, and the forth non-display area 130d provided with the heat line 162.

A heat line pad 163 connected to the main heat line 161 may be provided on an upper end of the pixel driving circuit layer 102 provided in the non-display area. However, the heat line pad 163 may not be provided.

The anode electrodes AE are patterned in the display area 120 of the planarization layer 103.

The bank 104 is provided in the display area 120 and the non-display area 130 to cover the planarization layer 103 and the anode electrodes AE.

The bank 104 provided in the display area 120 is patterned, and openings through which the anode electrodes AE are exposed are formed.

In this case, the bank 104 provided in the non-display area 130 may be patterned, so that the heat line 162 may be exposed as shown in FIG. 6B. However, the heat line 162 may be covered by the bank 104.

The light emitting layer 105 is provided in the display area 120 and the non-display area 130 to cover the bank 104 and the anode electrodes AE.

The heat line is covered by the light emitting layer 105 as illustrated in FIG. 6B.

Along the boundary line between the display area 120 and the non-display area 130, at least one of the planarization layer 103, the bank 104, the anode electrode AE and the light emitting layer 105 is patterned, forming the undercut area UC where an undercut structure 150 is provided.

In the undercut structure 150, the light emitting layer 105 is disconnected. Accordingly, the light emitting layer 105 is exposed on the side surface of the undercut structure 150.

As illustrated in FIG. 1, the undercut structure 150 is provided in the display area 120, is provided along the boundary line between the display area 120 and the non-display area 130, and is provided to face the second non-display area 130b, the third non-display area 130c, and the fourth non-display area 130d.

The undercut structure 150 is formed to disconnect the light emitting layer 105 at the interface between the display area 120 and the non-display area 130, and the disconnected side surface of the light emitting layer is covered by the cathode electrode 106.

The undercut structure 150 may be formed using the planarization layer 103 as shown in FIG. 6B. In other words, the undercut structure 150 shown in FIG. 6B may be formed by etching the protection layer 102′ 103 provided in the pixel driving circuit layer 102 and the planarization layer 103. In this case, the light emitting layer 105 and the cathode electrode 106 may be disconnected by the undercut structure 150.

However, the undercut structure 150 may be formed by etching the bank 104.

The undercut structures in various structures provided in the undercut area are described below.

In the above description, for convenience of description, it has been described that the undercut structure 150 is provided in the display area 120 as shown in FIG. 1, but the undercut structure 150 may be described as being included in the non-display area 130. In other words, the undercut structure 150 is provided at the outermost periphery of the display area 120 and may be provided in the boundary area between the display area 120 and the non-display area 130, so that the undercut structure 150 may be understood to be provided in the display area 120 or may be understood as being provided in the non-display area 130.

Specifically, assuming that the undercut structure 150 is provided in the display area 120, the undercut structure 150 is particularly provided at the outermost periphery of the display area 120. In this case, the heat line 162 is provided outside the undercut structure 150, that is, outside the display area 120. Accordingly, the heat line 162 is provided outside the display area 120, and the undercut structure 150 is provided inside the display area 120.

However, assuming that the undercut structure 150 is provided in the non-display area 130, the undercut structure 150 is provided outside the display area 120, and the heat line 162 is provided farther from the display area 120 than the undercut structure 150. In this case, the undercut structure 150 is provided between the display area 120 and the heat line 162.

As shown in FIG. 6B, the light emitting layer 105 is covered in the display area 120 and the non-display area 130 by the cathode electrode 106.

In the display area 120, the undercut structure 150 is provided along the heat line hole 140 and, in the undercut structure 150, the side surface of the light emitting layer 105, exposed to the side surface of the undercut structure 150, may be covered by the cathode electrode 106 provided in the undercut structure 150. In other words, the side surface of the light emitting layer 105 provided in the undercut structure 150 may be covered by the cathode electrode 106.

Specifically, at the interface between the display area 120 and the non-display area 130, the undercut structure 150 is formed to cover the side surface of the light emitting layer 105.

For example, moisture and oxygen introduced from the outside through the side surface of the encapsulation layer 108 or the periphery of the non-display area 130 to the light emitting layer 105 may not be moved to the display area 120 by the heat line hole 140, and the movement of the moisture and oxygen from the non-display area 130 to the display area 120 may slow down.

However, since the light emitting layer 105 is exposed at the side surface 141 of the heat line hole adjacent to the display area 120 among the side surfaces of the heat line hole 140, moisture and oxygen may penetrate through the light emitting layer 105 exposed to the side surface 141 of the heat line hole. The moisture and oxygen introduced through the light emitting layer 105 exposed to the side surface of the heat line hole may move along the light emitting layer 105 to the display area 120, damaging the light emitting elements ED in the display area 120.

In an aspect of the present disclosure, to prevent such damage, the undercut structure 150 may be provided along the interface between the display area 120 and the non-display area 130 as described above. The undercut area UC may be provided along the foreign matter blocking area FMBA including an area where the light emitting layer 105 and the cathode electrode 106 each are disconnected. The undercut area UC may be provided along the foreign matter blocking area FMBA in the display area.

In other words, as illustrated in FIG. 5 and described above, the side surface of the light emitting layer 105 exposed to the side surface of the undercut structure 150 is covered by the cathode electrode 106 provided in the undercut structure 150.

Accordingly, moisture and oxygen introduced through the light emitting layer 105 exposed to the side surface 141 of the heat line hole may not be further moved to the display area 120 by the cathode electrode 106 covering the side surface of the light emitting layer 105 at the side surface of the undercut structure 150.

Further, since the light emitting layer 105 is not exposed in the undercut structure 150, moisture and oxygen may not penetrate through the light emitting layer 105 in the undercut structure 150.

In other words, the undercut structure 150 may function to finally block moisture and oxygen between the display area 120 and the non-display area 130.

The capping layer 107 may be provided in the display area 120 and the non-display area 130 to cover the cathode electrode 106.

In this case, the capping layer 107 may cover the undercut structure 150 and may break in the undercut structure.

A voltage is applied to the cathode electrode 106 and the main heat line 161. In this case, the voltage applied to the main heat line 161 is also applied to the heat line 162.

Joule heating may be caused by the voltage applied to the heat line 162 and the cathode electrode 106, removing the light emitting layer 105, the cathode electrode 106 and the capping layer 107.

Accordingly, as shown in FIG. 6C, the heat line hole 140 may be formed in the area where the heat line 162 is provided. The light emitting layer 105 may be disconnected by the hot line hole 140.

The voltage and current applied to the heat line 162 and the cathode electrode 106 and the time when the voltage and current are applied may be set to vary depending on the thicknesses and materials of the light emitting layer 105, cathode electrode 106, and capping layer 107, the widths, thicknesses, and materials of the heat line 162 and the main heat line 161, and the number of the heat line pads 163.

In this case, the voltage and current applied to the heat line 162 and the cathode electrode 106 may be of direct current (DC) or be of alternating current (AC), such as pulses.

As shown in FIG. 6C, the heat line hole 140 surrounds the display area 120 and may be provided particularly along the undercut structure 150. In other words, the heat line hole 140 may be provided along the boundary line between the display area 120 and the non-display area 130 and be particularly provided to face the second non-display area 130b, the third non-display area 130c, and the fourth non-display area 130d.

The encapsulation layer 108 is provided in the display area 120 and the non-display area 130. The heat line 162 exposed through the heat line hole 140 is covered by the encapsulation layer.

As the encapsulation substrate 109 is attached to the top of the capping layer by the encapsulation layer 108, the light emitting display panel 100 with the cross section as shown in FIG. 5 is manufactured.

Hereinafter, various examples of the light emitting display device according to aspects of the present disclosure are described with reference to the drawings.

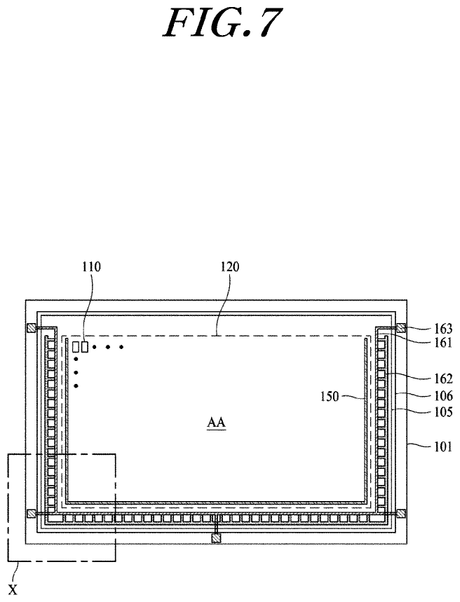

FIGS. 7, 8, and 9 are plan views illustrating a light emitting display panel applied to a light emitting display device according to aspects of the present disclosure.

The light emitting layer 105 and the cathode electrode 106 are provided in the display area 120 and the non-display area 130, and the heat line 162 is provided in the non-display area 130. The heat line 162 may be provided along the boundary line between the display area 120 and the non-display area 130 and be particularly provided along the boundary line between the second non-display area 130b, the third non-display area 130c, and the fourth non-display area 130d and the display area 120.

The undercut structure 150 may also be provided along the boundary line between the second non-display area 130b, the third non-display area 130c, and the fourth non-display area 130d and the display area 120.

In other words, the undercut structure 150 and the heat line 162 may be provided in parallel with each other. In this case, as described above, assuming that the undercut structure 150 and the heat line 162 are provided in the non-display area 130, the undercut structure 150 is provided closer to the display area 120 than the heat line 162. In other words, the undercut structure 150 is provided between the heat line 162 and the display area 120.

However, under the assumption that the undercut structure 150 is provided in the display area 120, and the heat line 162 is provided in the non-display area 130, the undercut structure 150 is provided at the outermost periphery of the display area 120, and the heat line 162 is provided outside the display area 120. In other words, the display area 120 and the non-display area 130 may be divided along the boundary between the undercut structure 150 and the heat line 162.

The heat line 162 is connected to the main heat line 161 provided on a layer different from the layer provided with the heat line. The heat line 162 may be provided in at least one of the second non-display area 130b, the third non-display area 130c, and the fourth non-display area 130d. The main heat line 161 may also be provided along the boundary line between the second non-display area 130b, the third non-display area 130c, and the fourth non-display area 130d and the display area 120. However, the arrangement structure of the main heat line 161 may be changed in various forms.

The heat line pad 163 connected to the main heat line 161 may be provided in the non-display area as illustrated in FIG. 7. In this case, the number of heat line pads 163 may be varied.

The heat line pad 163 may be provided in at least one of the second non-display area 130b, the third non-display area 130c, and the fourth non-display area 130d. At least one heat line pad 163 may be provided in any one of the second non-display area 130b, the third non-display area 130c, and the fourth non-display area 130d.

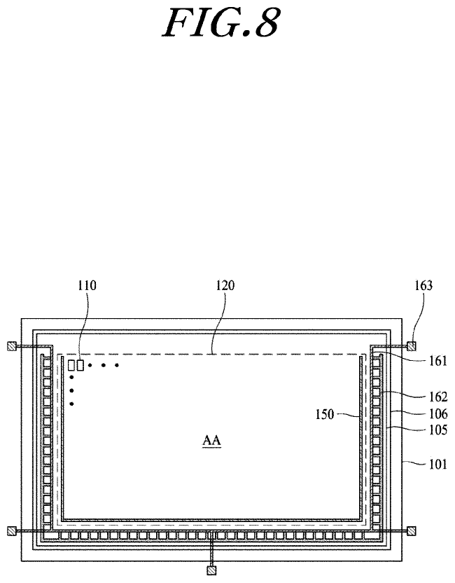

The main heat line 161 may be provided on the substrate in a floating state. For example, in the manufacturing process of the light emitting display panel 100, the light emitting display panel 100 may be provided on a mother substrate. The heat line pad 163 connected to the main heat line 161 may be provided, outside the light emitting display panel 100, on the mother substrate. In other words, the heat line pad 163 may be provided outside the light emitting display panel 100 as shown in FIG. 8.

In this case, Joule heat may be generated in the heat line 162 by the voltage applied through the heat line pad 163, and accordingly, a cross-sectional structure as shown in FIG. 5 may be formed. After the cross-sectional structure shown in FIG. 5 is formed, the light emitting display panel 100 may be separated from the mother substrate. Accordingly, the heat line pad 163 provided on the mother substrate is separated from the light emitting display panel 100.

Accordingly, the main heat line 161 provided on the light emitting display panel 100 separated from the mother substrate may be provided on the substrate in a floating state in which it is not connected to other electrodes.

The main heat line 161 may be connected to the power supply unit 500 supplying power to at least one of the driving transistor Tdr, the cathode electrode 106 or the anode electrodes AE.

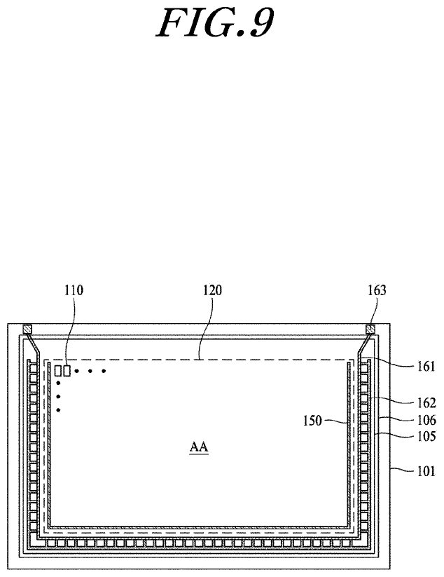

If the power supply unit 500 is provided on the main substrate connected to the light emitting display panel 100, the main heat line 161 may be connected to the main substrate through the first non-display area 130a and be connected to the power supply unit 500 on the main substrate as illustrated in FIG. 9.

In this case, the heat line pad 163 connected to the main heat line 161 may be provided in the first non-display area 130a as illustrated in FIG. 9. The heat line pad 163 provided in the first non-display area 130a may be connected to the power supply unit 500 provided on the main substrate through a chip-on-film (COF) where the data driver IC constituting the data driver 300 is mounted. If the main substrate is directly connected to the light emitting display panel 100 in the first non-display area 130a, the heat line pad 163 provided in the first non-display area 130a may be directly connected to the main substrate to be connected to the power supply unit 500 provided on the main substrate.

As described above, when the main heat line 161 is connected to the power supply unit 500, the main heat line 161 may be used as a power supply line for supplying gate driver power to the gate driver 200 provided in the non-display area 130. In other words, the main heat line 161 may be one of the power supply lines connected to the gate driver.

For example, as described with reference to FIG. 4, the gate driver may be supplied with gate driver power GVSS1, GVSS2, and VD, and to supply the gate driver power GVSS1, GVSS2, and VD, the power supply lines PL1, PL2, and PL3 may be provided.

In this case, one of the power supply lines PL1, PL2, and PL3 may be used as the main heat line 161. For example, the power supply line PL2 to which the second low voltage GVSS2 used as the gate-off signal is supplied may be used as the main heat line 161.

During the manufacturing process of the light emitting display panel 100, a high voltage may be applied to the main heat line 161, and a low voltage (e.g., 0 V) may be applied to the cathode electrode 106, so that Joule heat may be generated between the heat line 162 and the cathode electrode 106, thereby forming the heat line hole 140.

When the light emitting display device is driven after the manufacturing process of the light emitting display panel is completed, the second low voltage GVSS2 may be supplied to the main heat line 161, thereby generating a gate-off signal.

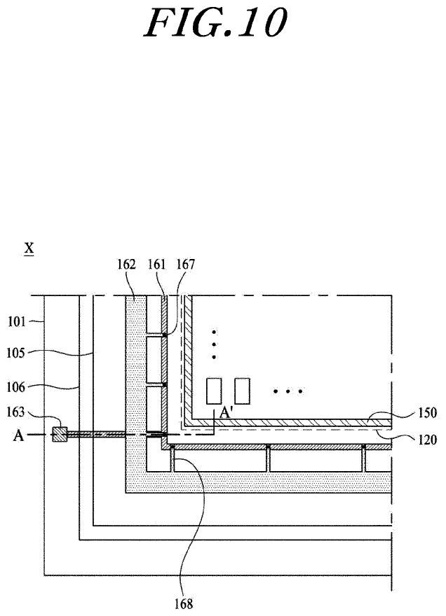

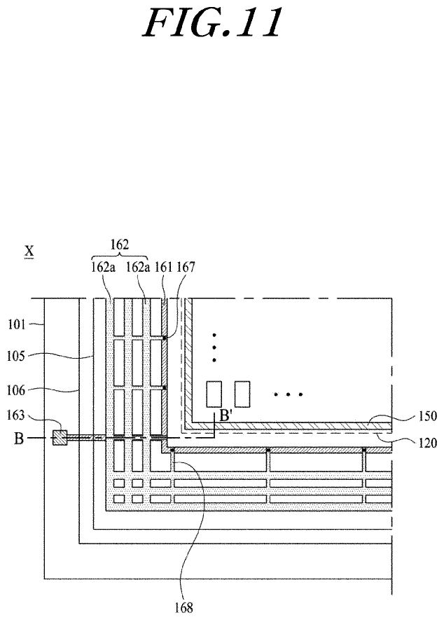

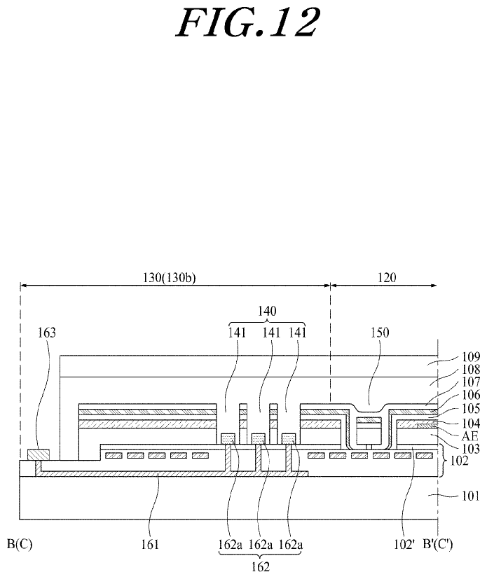

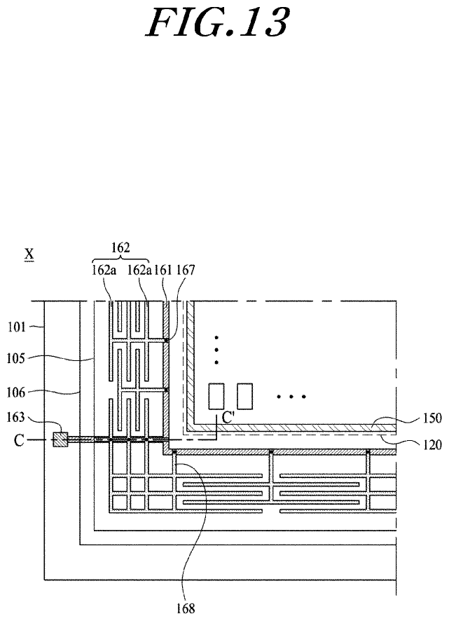

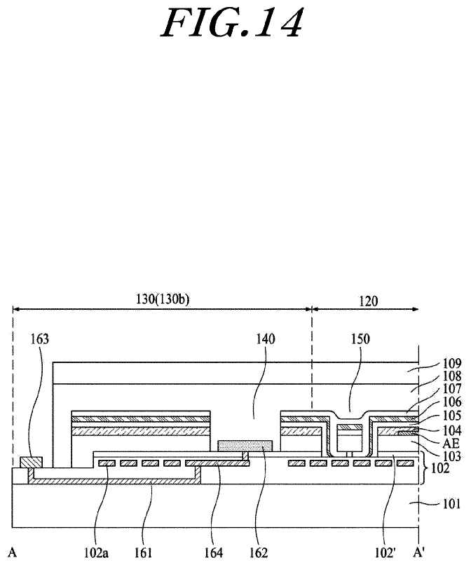

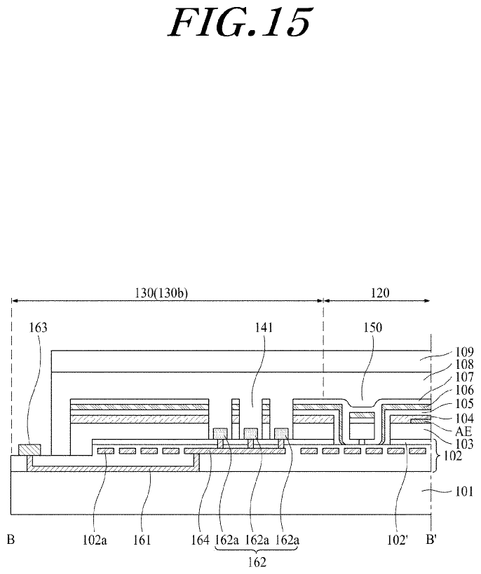

FIGS. 10, 11, 12, 13, 14, and 15 are exemplary views illustrating a structure of a light emitting display panel applied to a light emitting display device according to aspects of the present disclosure. For example, FIGS. 10 and 11 are exemplary enlarged views of area X of FIG. 7. FIG. 12 is an exemplary cross-sectional view taken along line C-C′ of FIG. 13. FIG. 14 is another exemplary cross-sectional view taken along line A-A′ of FIG. 10. FIG. 15 is another exemplary cross-sectional view taken along line B-B′ of FIG. 11. What is identical or similar to those described in connection with FIGS. 1 to 9 may be omitted or briefly described below.

FIG. 10 is an enlarged view of area X of FIG. 7. The cross section taken along line A-A′ of FIG. 10 may be the cross section of FIG. 5.

The main heat line 161 and the heat line 162 may be electrically connected through a plurality of contacts 167 as shown in FIG. 10. Accordingly, the heat line 162 may include connection portions 168 connected to the main heat line 161 through the contacts 167.

In this case, the heat line 162 except for the connection portions 168 may be formed as one line as shown in FIG. 10. The heat line 162 formed as one line may be continuously formed in the second non-display area 130b, the third non-display area 130c, and the fourth non-display area 130d. The heat line 162 including the connection portions 168 may be understood as one line as a whole.

The heat line 162 may include at least two auxiliary heat lines 162a electrically connected to each other as illustrated in FIGS. 11 to 13. In this case, the heat line hole 140 may include auxiliary heat line holes 141 respectively corresponding to the auxiliary heat lines 162a.

The auxiliary heat lines 162a may have various structures.

For example, the auxiliary heat lines 162a may be formed in a form physically connected to each other as shown in FIGS. 11 and 12 or be formed in a partially disconnected form as shown in FIG. 13. The cross-section taken along line B-B′ of FIG. 11 and the cross-section taken along line C-C′ of FIG. 13 may be the cross section of FIG. 12.

In other words, as illustrated in FIG. 12, the heat line hole 140 may include at least two auxiliary heat line holes 141.

As the number of auxiliary heat line holes 141 increases, areas where the light emitting layer 105 is disconnected increases, thus reducing movement and moving speed of moisture and oxygen through the light emitting layer 105.

The auxiliary heat lines 162a exposed through the auxiliary heat line holes 141 are covered by the encapsulation layer 108. In other words, the method for forming the auxiliary heat line holes 141 is the same as the method for forming the heat line holes 140 described with reference to FIGS. 6A to 6C.

As shown in FIGS. 14 and 15, the main heat line 161 may be connected to the gate driver auxiliary electrode 164 formed on the same layer as the gate driver electrodes 102a constituting the gate driver 200 provided in the non-display area 130, and the gate driver auxiliary electrode 164 may be connected to the heat line 162. In other words, the main heat line 161 may be connected to the heat line 162 through the gate driver auxiliary electrode 164.

In this case, the gate driver power required for the gate driver may be supplied through the gate driver auxiliary electrode 164.

In other words, FIG. 14 and FIG. 15 illustrate an exemplary in which the main heat line 161 is one of the power supply lines PL1, PL2, and PL3 connected to the gate driver 200 as described with reference to FIG. 9. In this case, the heat line pad 163 shown in FIGS. 14 and 15 may be substantially provided in the first non-display area 130a. The auxiliary gate driver electrode 164 may be connected to at least one of the gate driver electrodes 102a.

However, the gate driver auxiliary electrode 164 connecting the main heat line 161 and the heat line 162 may be provided in a floating state without being connected to the gate driver electrodes 102a. In this case, the gate driver auxiliary electrode 164 simply functions to connect the main heat line 161 and the heat line 162. In this case, the heat line pad 163 may be provided in the second non-display area 130b as shown in FIGS. 14 and 15.

FIG. 14 illustrates a cross section of a light emitting display panel in which the heat line 162 is formed as one line as shown in FIG. 10, and FIG. 15 illustrates a cross section of a light emitting display panel in which the heat line 162 includes three auxiliary heat lines 162a as shown in FIGS. 11 to 13.

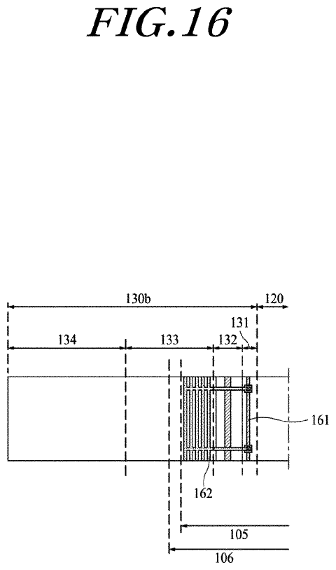

FIGS. 16, 17A, 17B, 17C, 18A, 18B, 19A, 19B, 20A, 20B, and 20C are exemplary views illustrating the positions of a heat line and a main heat line in a light emitting display device according to aspects of the present disclosure. What is identical or similar to those described in connection with FIGS. 1 to 15 may be omitted or briefly described below.

As described above, the non-display area 130 may include the first non-display area 130a to the fourth non-display area 130d.

In this case, as shown in FIG. 16, the second non-display area 130b in which the gate driver 200 includes a first area 131 adjacent to the display area 120, a second area 132 adjacent to the first area 131 and provided with power supply lines PL1, PL2, and PL3 for supplying power to the gate driver, a third area 133 adjacent to the second area and provided with transistors constituting the gate driver, and a fourth area 134 provided with at least one clock line CL for supplying at least one gate clock CLK to the gate driver 200. The heat line 162 may be provided in at least one of the first area or the third area.

Referring to FIG. 16, the light emitting layer 105 may be provided in the display area 120 and a portion of the non-display area 130, e.g., a portion of the third area 133. In other words, the light emitting layer 105 may be designed to be provided even in the second area 132, but may penetrate up to the third area 133 during the manufacturing process.

The cathode electrode 106 should cover the light emitting layer 105. Accordingly, the cathode electrode 106 may be provided in the display area 120 and a portion of the third area 133. In particular, since the cathode electrode 106 has to cover the light emitting layer 105, an end of the cathode electrode 106 is positioned more adjacent to the fourth area 134 than an end of the light emitting layer 105.

In this case, the heat line 162 may be connected to the main heat line 161 provided on a layer different from the layer provided with the heat line 162. The heat line 162 may be provided in the third area, and the main heat line 161 may be provided in the first area 131 or the second area 132.

For example, in the light emitting display panel shown in FIG. 16, the main heat line 161 is provided in the first area 131.

A line extending from the first non-display area 130a to the fourth non-display area 130d may not be provided in the first area 131. Gate lines extending from the gate driver 200 may be provided in the first area 131.

Accordingly, since the main heat line 161 is provided in the empty space, an additional space for disposing the main heat line 161 is not required, so that the width of the second non-display area 130b may not be increased as compared with the conventional art.

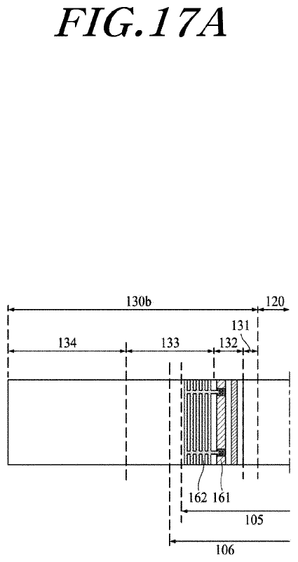

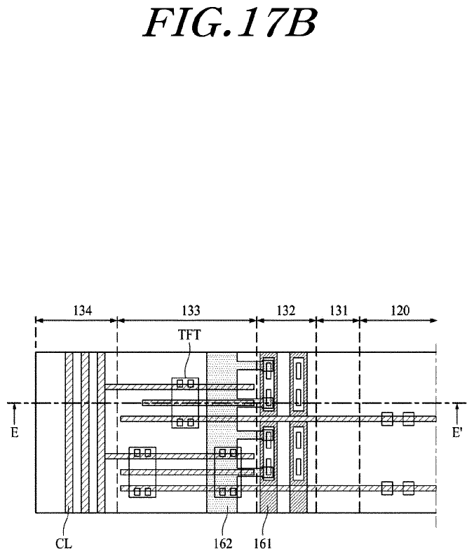

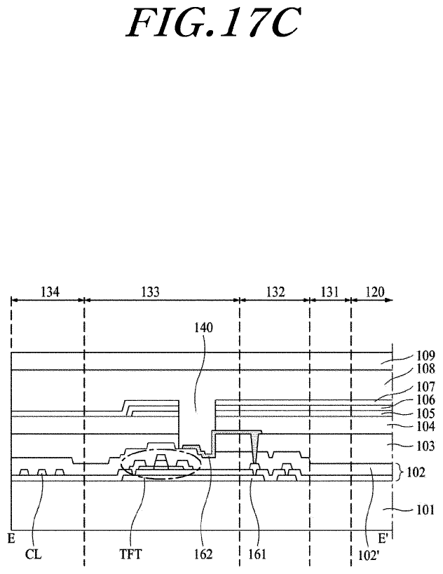

Referring to FIGS. 17A to 17C, the heat line 162 may be connected to the main heat line 161 provided on a layer different from the layer provided with the heat line 162. The heat line 162 may be provided in the third area, and the main heat line 161 may be provided in the second area 132. FIG. 17B is an exemplary view specifically illustrating the circuits of FIG. 17A, and FIG. 17 is an exemplary cross-sectional view taken along line E-E′ of FIG. 17B.

As described above, at least one power supply line and a main heat line 161 may be provided in the second area 132. In this case, the main heat line 161 may be any one of the power supply lines PL1, PL2, and PL3. However, the main heat line 161 provided in the second area 132 may be an independent line maintained in a floating state without being connected to the gate driver 200.

Transistors TFTs constituting the gate driver 200 may be provided in the third area 133, and at least one clock line CL may be provided in the fourth area 134.

If one of the power supply lines is connected to the main heat line 161, an additional space for disposing the main heat line 161 is not required, so that the width of the second non-display area 130b may not be increased as compared with the conventional art.

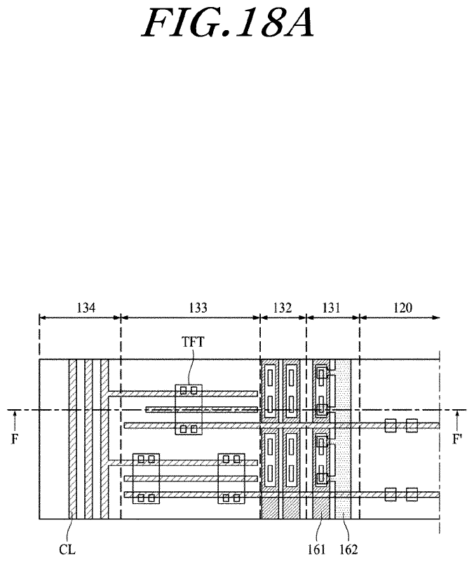

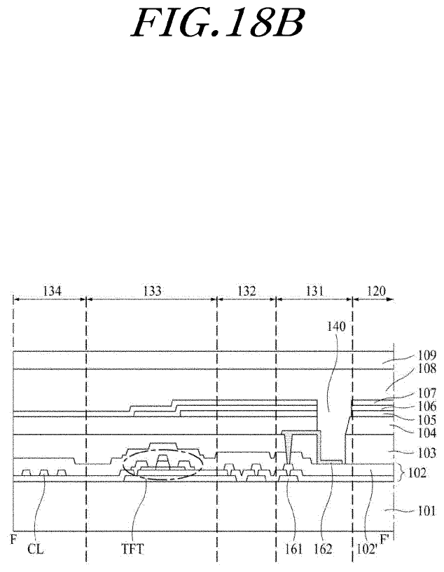

Referring to FIGS. 18A and 18B, the main heat line 161 and the heat line 162 may be provided in the first area 131. FIG. 18B is an exemplary cross-sectional view taken along line F-F′ of FIG. 18A.

Since the main heat line 161 and the heat line 162 may be provided in the empty first area 131, spacings from other lines need not be considered, and thus, various changes may be made to the arrangement structure of the main heat line 161 and the heat line 162.

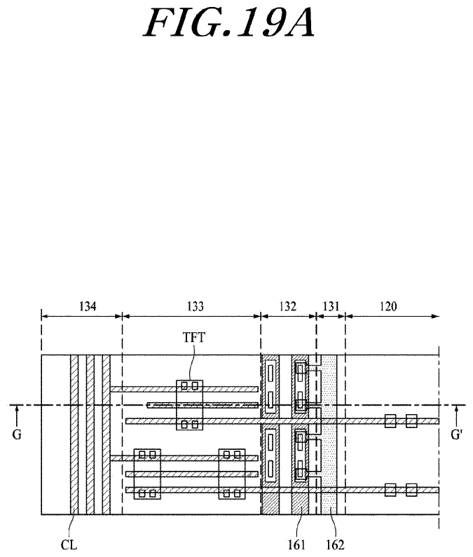

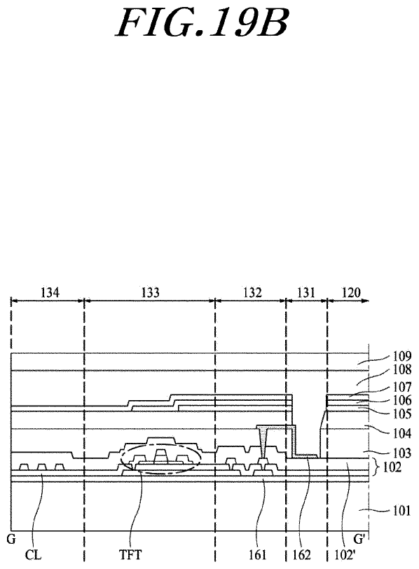

Referring to FIGS. 19A and 19B, the main heat line 161 may be provided in the second area 132, and the heat line 162 may be provided in the first area 131. FIG. 19B is an exemplary cross-sectional view taken along line G-G′ of FIG. 19A.

In this case, the main heat line 161 may be any one of the power supply lines PL1, PL2, and PL3. However, the main heat line 161 may be an independent line maintained in a floating state without being connected to the gate driver 200.

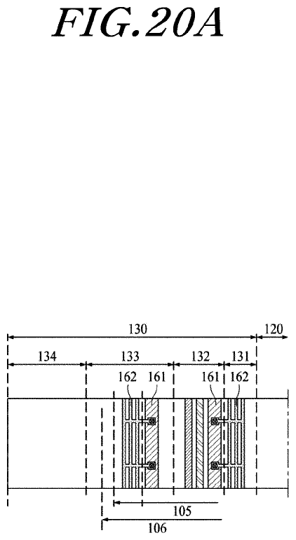

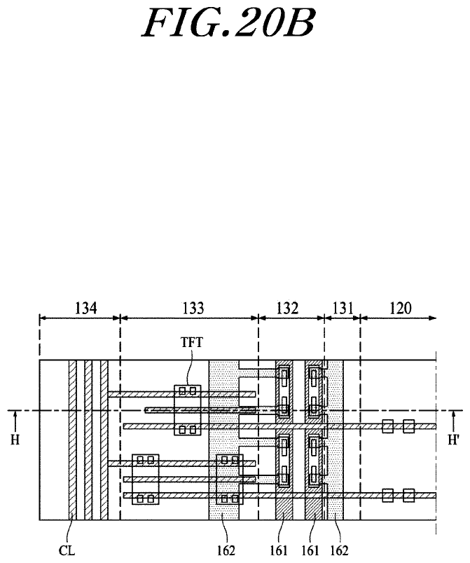

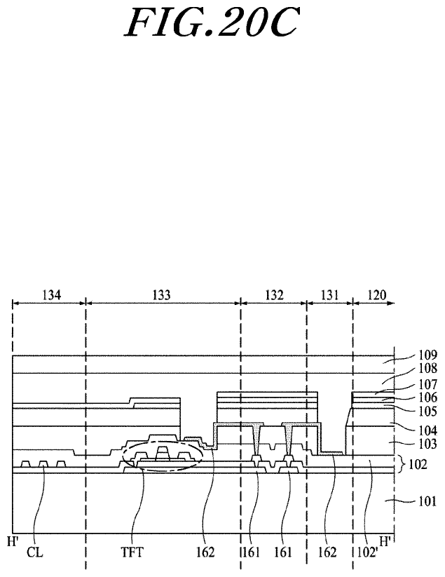

Referring to FIGS. 20A to 20C, the heat line 162 may be connected to the main heat line 161 provided on a layer different from the layer provided with the heat line 162. The heat line 162 may be provided in the first area and the third area 133, and the main heat line 161 may be provided in the second area. FIG. 20B is an exemplary view specifically illustrating the areas of FIG. 20A, and FIG. 20C is an exemplary cross-sectional view taken along line H-H′ of FIG. 20B.

As described above, the heat line 162 and the main heat line 161 may be provided in various structures in the first area 131 to the third area 133. Accordingly, the arrangement structure of the heat line 162 and the main heat line 161 may be set to vary considering the structure of the circuits provided in the first area 131 to the third area 133, the widths of the first area 131 to the third area 133, and the width of the second non-display area 130b.

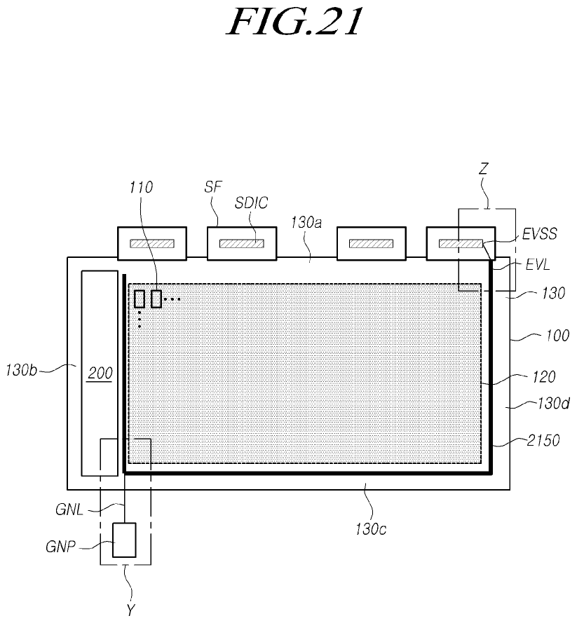

FIG. 21 is a plan view illustrating a light emitting display panel applied to a light emitting display device according to aspects of the present disclosure. What is identical or similar to those described in connection with FIGS. 1 to 20C may be omitted or briefly described below.

The light emitting layer 105 and the cathode electrode 106 may be provided in the display area 120 and the non-display area 130, and a foreign matter blocking area including a structure capable of delaying penetration of moisture and oxygen into the display area may be disposed in the non-display area 130. In addition, an undercut area having an undercut structure 2150 may be disposed in the non-display area 130 or the display area 120.

The undercut area may be provided along the boundary line between the display area 120 and the non-display area 130 and be particularly provided along the boundary line between the second non-display area 130b, the third non-display area 130c, and the fourth non-display area 130d and the display area 120.

The undercut structure 2150 may also be provided along the boundary line between the second non-display area 130b, the third non-display area 130c, and the fourth non-display area 130d and the display area 120.

In other words, the undercut structure 2150 and the foreign matter blocking area may be provided in parallel with each other. For example, as described above, when the undercut structure 2150 and the foreign matter blocking area are provided in the non-display area 130, the undercut structure 2150 may be provided closer to the display area 120 than the foreign matter blocking area. In other words, the undercut structure 2150 may be provided between the foreign matter blocking area and the display area 120.

When the undercut structure 2150 is provided in the display area 120, and the foreign matter blocking area is provided in the non-display area 130, the undercut structure 2150 may be provided at the outermost periphery of the display area 120, and the foreign matter blocking area may be provided outside the display area 120. In other words, the display area 120 and the non-display area 130 may be divided along the boundary between the undercut structure 2150 and the foreign matter blocking area.

As described above, in the light emitting display device according to aspects of the present disclosure, the foreign matter blocking area may be provided in the non-display area 130 and, simultaneously, the undercut structure 2150 may be provided in the display area 120 or the non-display area 130, but aspects of the present disclosure are not limited thereto.

For example, in the light emitting display device according to aspects of the present disclosure, the foreign matter blocking area may be provided in the non-display area 130 but the undercut structure 2150 may be not provided in the display area 120 or the non-display area 130.

For example, in the light emitting display device according to aspects of the present disclosure, the undercut structure 2150 may be provided in the display area 120 or the non-display area 130 but the foreign matter blocking area may be not provided in the non-display area 130.

The side surface of the light emitting layer 105 that is exposed to the side surface of the undercut structure 2150 may be covered by the cathode electrode 106 provided in the undercut structure 2150. In other words, the side surface of the light emitting layer 105 provided in the undercut structure 2150 may be covered by the cathode electrode 106.

The moisture and oxygen introduced through the light emitting layer 105 exposed in the foreign matter blocking area may not be further moved to the display area 120 by the cathode electrode 106 covering the side surface of the light emitting layer 105 at the side surface of the undercut structure 2150.

Further, since the light emitting layer 105 is not exposed in the undercut structure 2150, moisture and oxygen may not penetrate through the light emitting layer 105 in the undercut structure 2150.

In other words, the undercut structure 2150 may function to finally block moisture and oxygen between the display area 120 and the non-display area 130.

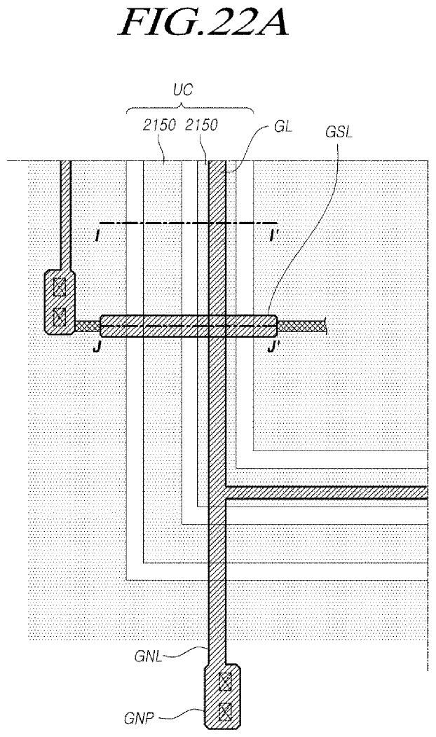

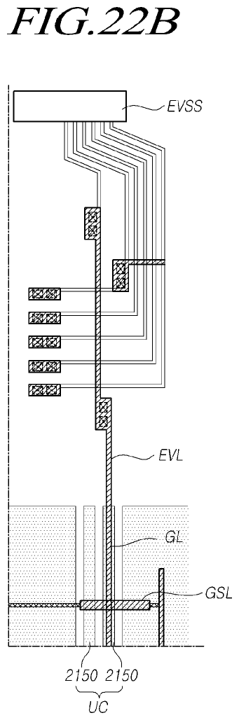

FIGS. 22A and 22B each are enlarged exemplary views illustrating Y area and Z area of FIG. 21 according to aspects of the present disclosure. What is identical or similar to those described in connection with FIGS. 1 to 21 may be omitted or briefly described below.

Referring to FIGS. 22A and 22B, a gate line GL that is a metal serving as a sacrificial layer may be disposed under the undercut structure 2150. The sacrificial layer may include the gate line GL. When one end of the gate line GL is connected to the cathode electrode and exists in a floating state, an irregular capacitance is formed, which may interfere with the gate signal operation. Since the metal serving as the sacrificial layer is connected to the cathode electrode, it is necessary to ensure that the metal and cathode electrode are equal potential.

Referring to FIG. 22A, one end of the gate line GL is connected to the ground line GNL connected to the ground pad GNP so that the metal serving as the sacrificial layer and cathode can be equal potential.

Referring to FIG. 22B, one end of the gate line GL is connected to the low-potential power line EVL connected to the low-potential power source EVSS so that the metal serving as the sacrificial layer and cathode electrode can be equal potential.

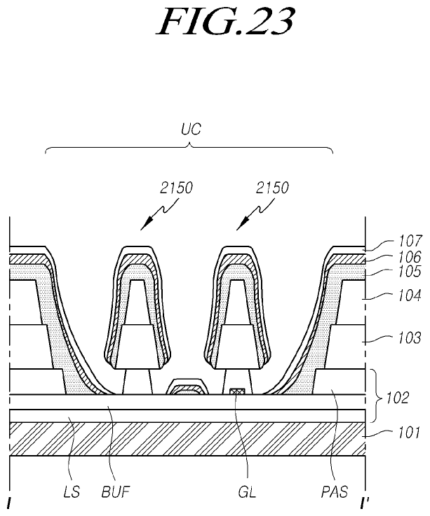

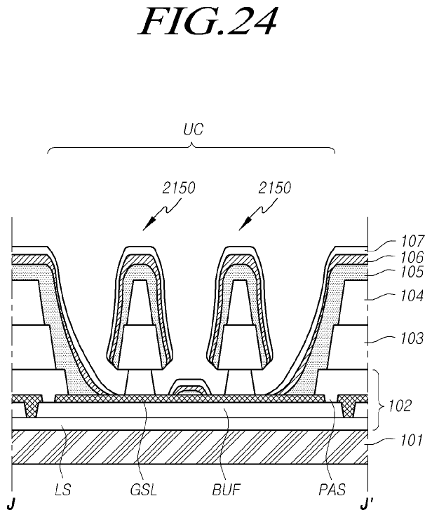

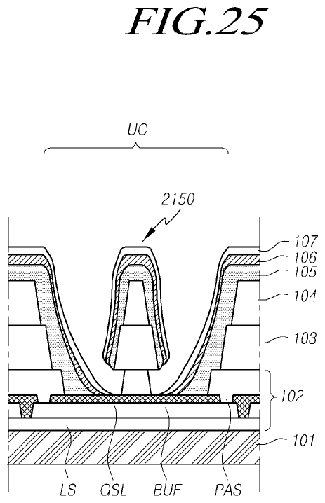

FIGS. 23 to 30 are exemplary views illustrating an undercut structure 2150 provided in an undercut area UC in a light emitting display device according to aspects of the present disclosure. For example, FIG. 23 is exemplary cross-sectional views taken along line I-I′ of FIG. 22A and FIG. 24 is exemplary cross-sectional views taken along line J-J′ of FIG. 22A. FIGS. 25 to 30 illustrate aspects of a structure in which an undercut structure is disposed. What is identical or similar to those described in connection with FIGS. 1 to 22B may be omitted or briefly described below.

In the undercut area UC, at least one of the pixel driving circuit layer 102, the planarization layer 103, the bank 104, the anode electrode, or the light emitting layer 105 may be patterned to form an undercut structure 2150.

The pixel driving circuit layer 102 may further include a light shield layer LS, a buffer layer BUF, a protection layer PAS, a sacrificial layer, and an interlayer insulating layer. In the undercut area UC, at least one of the protection layer PAS, the sacrificial layer, or the interlayer insulating layer may be patterned to form the undercut structure 2150.

The sacrificial layer may be a gate sacrificial layer GSL or an active sacrificial layer ASL.

FIGS. 23 and 24 illustrate aspects of a structure in which two undercut structures 2150 are continuously disposed.

Referring to FIG. 23, in the two undercut structures 2150, the protection layer PAS, the planarization layer 103, and the bank 104 may be stacked on the buffer layer BUF in the left undercut structure, and the gate line GL, the protection layer PAS, the planarization layer 103, and the bank 104 may be stacked on the buffer layer BUF in the right undercut structure. The protection layer PAS on the buffer layer BUF may be etched to form the undercut structure 2150 under the planarization layer 103.

Referring to FIG. 24, the gate sacrificial layer GSL, the protection layer PAS, the planarization layer 103, and the bank 104 may be stacked on the buffer layer BUF in the two undercut structures 2150. The protection layer PAS on the gate sacrificial layer GSL may be etched to form the undercut structure 2150 under the planarization layer 103.

FIGS. 25 to 30 illustrate aspects of a structure in which an undercut structure 2150 is disposed.

Referring to FIG. 25, the gate sacrificial layer GSL, the protection layer PAS, the planarization layer 103, and the bank 104 may be stacked on the buffer layer BUF. The protection layer PAS on the gate sacrificial layer GSL may be etched to form the undercut structure 2150 under the planarization layer 103.

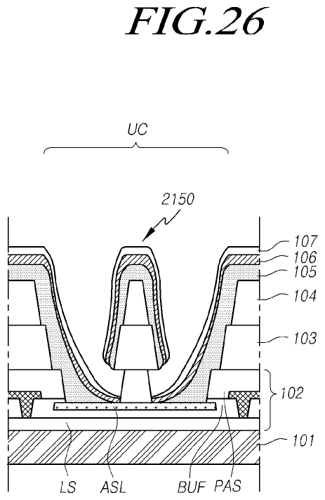

Referring to FIG. 26, the active sacrificial layer ASL, the interlayer insulating layer (not shown), the protection layer PAS, the planarization layer 103 and the bank 104 may be stacked on the buffer layer BUF. The interlayer insulating layer (not shown) and the protection layer PAS on the active sacrificial layer ASL may be etched to form an undercut structure 2150 under the planarization layer 103.

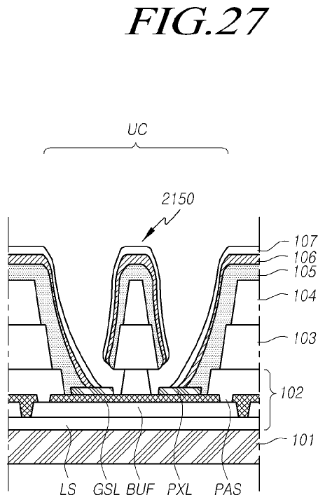

Referring to FIG. 27, the gate sacrificial layer GSL, the pixel electrode PXL, the protection layer PAS, the planarization layer 103, and the bank 104 may be stacked on the buffer layer BUF. The pixel electrode PXL and the protection layer PAS on the gate sacrificial layer GSL may be etched to form the undercut structure 2150 under the planarization layer 103.

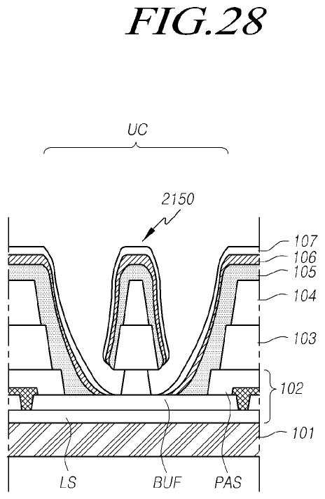

Referring to FIG. 28, the gate sacrificial layer GSL, the protection layer PAS, the planarization layer 103, and the bank 104 may be stacked on the buffer layer BUF. The gate sacrificial layer GSL and protection layer PAS on the buffer layer BUF may be etched to form the undercut structure 2150 under the planarization layer 103.

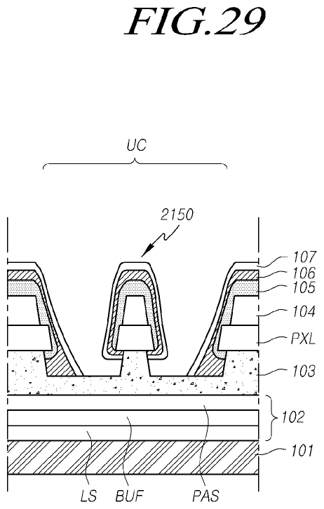

Referring to FIG. 29, the protection layer PAS, the planarization layer 103, the pixel electrode PXL, and the bank 104 may be stacked on the buffer layer BUF, and a portion of the planarization layer 103 on the protection layer PAS may be etched to form the undercut structure 2150 under the pixel electrode PXL.

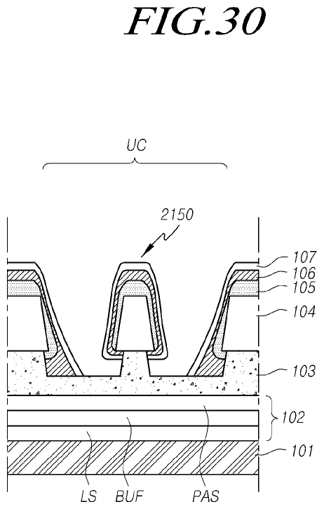

Referring to FIG. 30, the protection layer PAS, the planarization layer 103 and the bank 104 may be stacked on the buffer layer BUF, and a portion of the planarization layer 103 on the protection layer PAS may be etched to form the undercut structure 2150 under the bank 104.

The light emitting layer 105 and the cathode electrode 106 may be disconnected by the undercut structure 2150.

The side surface of the light emitting layer 105 that is exposed to the side surface of the undercut structure 2150 may be covered by the cathode electrode 106 provided in the undercut structure 2150. In other words, the side surface of the light emitting layer 105 provided in the undercut structure 2150 may be covered by the cathode electrode 106.

The moisture and oxygen introduced through the light emitting layer 105 outside the light emitting display panel may not be further moved to the display area 120 by the cathode electrode 106 covering the side surface of the light emitting layer 105 at the side surface of the undercut structure 2150.

In other words, the undercut structure 2150 may function to finally block moisture and oxygen between the display area 120 and the non-display area 130.

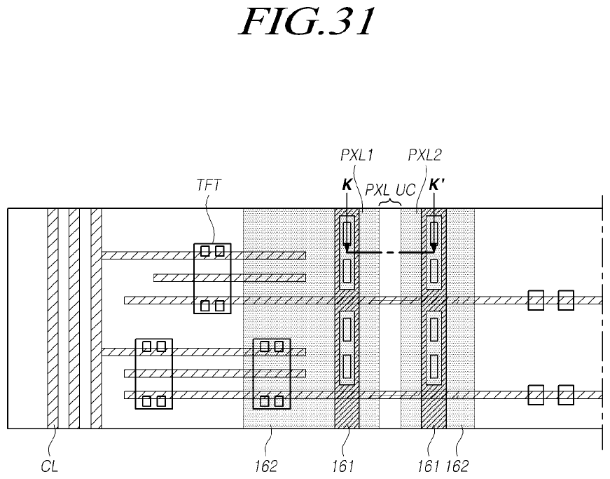

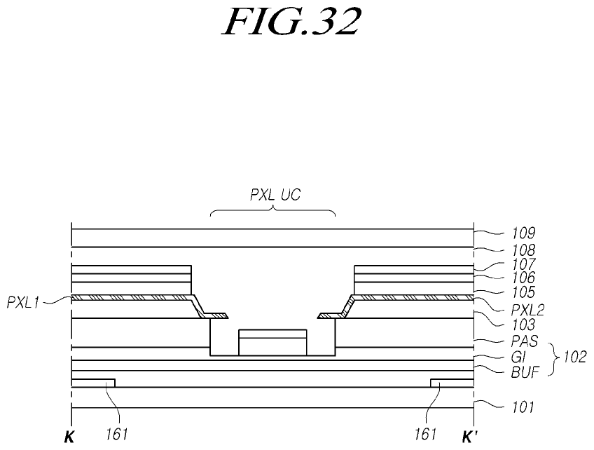

FIGS. 31 and 32 are exemplary views illustrating an undercut structure provided in a pixel undercut area PXL UC in a light emitting display device according to aspects of the present disclosure. For example, FIG. 31 is a plan view illustrating an undercut structure provided in the pixel undercut area PXL UC, and FIG. 32 is an exemplary cross-sectional view taken along line K-K′ of FIG. 31. What is identical or similar to those described in connection with FIGS. 1 to 30 may be omitted or briefly described below.

Referring to FIGS. 31 and 32, a pixel undercut area PXL UC may be disposed between gate driver power patterns connected to the power supply lines PL1, PL2, and PL3 provided to supply gate driver powers GVSS1, GVSS2 and VD.

The pixel undercut area PXL UC may surround the display area and may be disposed in the non-display area along the foreign matter blocking area surrounding the display area and including the area where the light emitting layer and the cathode electrode each are disconnected.

A heat line 162 may be provided in the foreign matter blocking area, and the heat line 162 may be connected to the main heat line 161 provided on a layer different from the layer provided with the heat line. The heat line 162 may be extended to the pixel undercut area PXL UC to form the anode electrodes PXL1 and PXL2.

The main heat line 161 connected to the heat line 162 may be used as a power supply line for supplying gate driver power to the gate driver 200 provided in the non-display area 130. In other words, the main heat line 161 may be one of the power supply lines PL1, PL2, and PL3 connected to the gate driver.

The pixel undercut area PXL UC may be provided along the boundary line between the display area 120 and the non-display area 130 and be particularly provided along the boundary line between the second non-display area 130b, the third non-display area 130c, and the fourth non-display area 130d and the display area 120.

In other words, the pixel undercut area PXL UC and the foreign matter blocking area may be provided in parallel with each other. For example, when the pixel undercut area PXL UC and the foreign matter blocking area are provided in the non-display area 130, the pixel undercut area PXL UC may be provided closer to the display area 120 than the foreign matter blocking area. In other words, the pixel undercut area PXL UC may be provided between the foreign matter blocking area and the display area 120.

As described above, in the light emitting display device according to aspects of the present disclosure, the foreign matter blocking area may be provided in the non-display area 130 and, simultaneously, the pixel undercut area PXL UC may be provided in the non-display area 130, but aspects of the present disclosure are not limited thereto.

For example, in the light emitting display device according to aspects of the present disclosure, the foreign matter blocking area may be provided in the non-display area 130 but the pixel undercut area PXL UC may be not provided in the non-display area 130.

For example, in the light emitting display device according to aspects of the present disclosure, the pixel undercut area PXL UC may be provided in the non-display area 130 but the foreign matter blocking area may be not provided in the non-display area 130.

Referring to FIGS. 31 and 32, an interlayer insulating layer GI, a protection layer PAS, and a planarization layer 103 are stacked on the buffer layer BUF. The planarization layer 103 is patterned and disposed along the area where the pixel undercut area PXL UC is disposed. The anode electrodes PXL1 and PXL2 are patterned to be disconnected and are disposed on the planarization layer 103 and the protection layer PAS.

The anode electrodes PXL1 and PXL2 may be provided by extending the heat line 162, and the heat line 162 may be connected to the main heat line 161 provided on a layer different from the layer provided with the heat line 162. The anode electrodes PXL1 and PXL2 may be connected to the main heat line 161 through the heat line 162. The main heat line 161 may be one of the power supply lines PL1, PL2, and PL3 connected to the gate driver.

The protection layer PAS and a portion of the interlayer insulating layer GI are etched by treating the protection layer PAS and the interlayer insulating layer GI with a high-concentration buffered oxide etch (BOE), forming an undercut structure under the anode electrodes PXL1 and PXL2.

In other words, the pixel undercut area PXL UC may be disposed as the planarization layer 103 is disconnected, and the undercut structure in which the anode electrodes PXL1 and PXL2 are disposed protruding further outward than an end of the planarization layer 103 may be disposed

The light emitting layer 105 and the cathode electrode 106 may be disposed on the anode electrodes PXL1 and PXL2, and the light emitting layer 105 and the cathode electrode 106 may be disposed further inward than the ends of the anode electrodes PXL1 and PXL2.

Further, the light emitting layer 105 and the cathode electrode 106 may be disposed on the pixel driving circuit layer 102 in the area where the planarization layer 103 is disconnected, and the light emitting layer 105 and the cathode electrode 106 may be disposed not to overlap the ends of the anode electrodes PXL1 and PXL2.

The light emitting display device according to aspects of the present disclosure may include a capping layer 107 that covers the cathode electrode 106, an encapsulation layer 108 provided on the side surfaces and upper surface of the capping layer 107, and an encapsulation substrate 109 attached to the top of the capping layer 107 through the encapsulation layer 108.

A heat line 162 may be provided in the foreign matter blocking area, and a heat line hole may be provided in the light emitting layer provided in the foreign matter blocking area. The heat line 162 may be connected to the main heat line 161 provided on a layer different from the layer provided with the heat line. The anode electrode may be connected to the main heat line 161.

The main heat line 161 may be connected to the gate driver auxiliary electrode formed on the same layer as the gate driver electrodes constituting the gate driver provided in the non-display area. The gate driver auxiliary electrode may be connected to the heat line 162.

Aspects of the present disclosure may provide a light emitting display device that may restrain or delay penetration into the display area of the moisture and oxygen, introduced through the side surface of the light emitting layer on the outermost periphery of the light emitting display panel by placing a structure, which is capable of delaying penetration of moisture and oxygen into the display area on the periphery of the light emitting display panel.

The foregoing aspects are briefly described below.

A light emitting display device according to aspects of the present disclosure may comprise a substrate divided into a display area and a non-display area surrounding the display area, a pixel driving circuit layer provided on the substrate and including a driving transistor, a planarization layer covering the pixel driving circuit layer, anode electrodes provided on the planarization layer and respectively provided in pixels, banks disposed between the anode electrodes, a light emitting layer disposed on the anode electrodes and the banks, a cathode electrode disposed on the light emitting layer, a capping layer covering the cathode electrode, an encapsulation layer provided on side surfaces and an upper surface of the capping layer, and an encapsulation substrate attached to an upper end of the capping layer through the encapsulation layer.

In the light emitting display device according to aspects of the present disclosure, the light emitting layer and the cathode electrode may be provided in the display area and the non-display area. The non-display area may include an area where the light emitting layer and the cathode electrode each are disconnected. The area where the light emitting layer and the cathode electrode each are disconnected may include a foreign matter blocking area where the pixel driving circuit layer is covered by the encapsulation layer and which surrounds the display area.

A heat line may be provided in the foreign matter blocking area. A heat line hole may be provided in the light emitting layer provided in the foreign matter blocking area. The heat line hole may surround the display area. The heat line exposed through the heat line hole may be covered by the encapsulation layer.

The heat line may be connected to the main heat line provided on a layer different from the layer provided with the heat line.

A heat line pad connected with a main heat line may be provided in the non-display area.

The main heat line may be provided on the substrate, in a floating state.

The main heat line may be connected with a power supply unit supplying power to at least one of the driving transistor, the cathode electrode, or the anode electrodes.

The main heat line may be used as a power supply line supplying gate driver power to a gate driver provided in the non-display area. The gate driver may supply gate signals to gate lines provided in the display area.

The main heat line may be connected to a gate driver auxiliary electrode formed on the same layer as the gate driver electrodes constituting the gate driver provided in the non-display area. The gate driver auxiliary electrode may be connected to the heat line.

Gate driver power necessary for the gate driver may be supplied through the gate driver auxiliary electrode.

The heat line may include at least two auxiliary heat lines electrically connected with each other. The heat line hole may include auxiliary heat line holes respectively corresponding to the auxiliary heat lines.

The auxiliary heat lines exposed through the auxiliary heat line holes may be covered by the encapsulation layer.

The non-display area may include a first non-display area provided with a data driver supplying data voltages to data lines provided in the display area, a second non-display area provided with a gate driver supplying gate signals to gate lines provided in the display area, a third non-display area facing the first non-display area, and a fourth non-display area facing the third non-display area.

The second non-display area may include a first area adjacent to the display area, a second area adjacent to the first area and provided with power supply lines supplying power to the gate driver, a third area adjacent to the second area and provided with transistors constituting the gate driver, and a fourth area provided with at least one clock line supplying at least one clock to the gate driver. The heat line may be provided in at least one of the first area or the third area.

The heat line may be connected with a main heat line provided on a different layer from a layer where the heat line is provided. The heat line may be provided in the third area. The main heat line may be provided in the first area or the second area.

The heat line may be connected with a main heat line provided on a different layer from a layer where the heat line is provided. The heat line may be provided in the first area and the third area. The main heat line may be provided in the second area.

The heat line may be provided in at least one of the first non-display area, the second non-display area, the third non-display area, or the fourth non-display area.

In the light emitting display device according to aspects of the present disclosure, the non-display area may include a foreign matter blocking area surrounding the display area and including an area where the light emitting layer and the cathode electrode each are disconnected. An undercut area may be provided along the foreign matter blocking area. A side surface of the light emitting layer provided in the undercut area may be covered by the cathode electrode.

The undercut area may be provided along the foreign matter blocking area in the display area.

The undercut area may be provided between the display area and the foreign matter blocking area.

The undercut area may be provided as at least one of a pixel driving circuit layer, a planarization layer, a bank, an anode electrode, or a light emitting layer is patterned.

The pixel driving circuit layer may include a protection layer, a sacrificial layer, and an interlayer insulating layer. The undercut area may be provided as at least one of the protection layer, the sacrificial layer or the interlayer insulating layer is patterned.

The sacrificial layer may include a gate line. The gate line may be connected with a ground line or a low-potential power line.

A light emitting display device according to aspects of the present disclosure may comprise a substrate divided into a display area and a non-display area surrounding the display area, a pixel driving circuit layer provided on the substrate and including a driving transistor, a planarization layer covering the pixel driving circuit layer, anode electrodes provided on the planarization layer and respectively provided in pixels, a light emitting layer disposed on the anode electrodes, and a cathode electrode disposed on the light emitting layer.

In the light emitting display device according to aspects of the present disclosure, the non-display area may include a foreign matter blocking area surrounding the display area and including an area where the light emitting layer and the cathode electrode each are disconnected. A pixel undercut area may be disposed in the non-display area, along the foreign matter blocking area.

The pixel undercut area may be disposed as the planarization layer is disconnected and have an undercut structure in which the anode electrode is disposed protruding further outward than an end of the planarization layer.

The light emitting layer and the cathode electrode may be disposed further inward than an end of the anode electrode.

The light emitting layer and the cathode electrode may be disposed on the pixel driving circuit layer in an area where the planarization layer is disconnected. The light emitting layer and the cathode electrode may be disposed not to overlap an end of the anode electrode.

The light emitting display device according to aspects of the present disclosure may further comprise a capping layer covering the cathode electrode, an encapsulation layer provided on side surfaces and an upper surface of the capping layer, and an encapsulation substrate attached to an upper end of the capping layer through the encapsulation layer.

A heat line may be provided in the foreign matter blocking area, and a heat line hole may be provided in the light emitting layer provided in the foreign matter blocking area.

The heat line may be connected to a main heat line provided on a layer different from the layer provided with the heat line.

The anode electrode may be connected to the main heat line.

The main heat line may be connected to a gate driver auxiliary electrode formed on the same layer as the gate driver electrodes constituting the gate driver provided in the non-display area. The gate driver auxiliary electrode may be connected to the heat line.

The above description has been presented to enable any person skilled in the art to make and use the technical idea of the present disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present disclosure. The above description and the accompanying drawings provide an exemplary of the technical idea of the present disclosure for illustrative purposes only. That is, the disclosed aspects are intended to illustrate the scope of the technical idea of the present disclosure.

What is claimed is:

1. A light emitting display device, comprising:
a substrate divided into a display area and a non-display area surrounding the display area;
a pixel driving circuit layer disposed on the substrate and including a driving transistor;
a planarization layer covering the pixel driving circuit layer;
anode electrodes provided on the planarization layer in pixels;
banks disposed between the anode electrodes;
a light emitting layer disposed on the anode electrodes and the banks;
a cathode electrode disposed on the light emitting layer;
a capping layer covering the cathode electrode;
an encapsulation layer disposed on side surfaces and an upper surface of the capping layer; and
an encapsulation substrate attached on the capping layer through the encapsulation layer,
a foreign matter blocking area disposed in the non-display area where the light emitting layer and the cathode electrode are disconnected and the pixel driving circuit layer is covered by the encapsulation layer and the foreign matter blocking area surrounding the display area.

2. The light emitting display device of claim 1, further comprising a heat line disposed in the foreign matter blocking area and a heat line hole disposed in the light emitting layer provided in the foreign matter blocking area,
wherein the heat line hole surrounds the display area, and the heat line is exposed through the heat line hole covered by the encapsulation layer.

3. The light emitting display device of claim 2, wherein the heat line is connected with a main heat line provided on a different layer from a layer where the heat line is provided.

4. The light emitting display device of claim 3, further comprising a heat line pad connected with the main heat line provided in the non-display area.

5. The light emitting display device of claim 3, wherein the main heat line is provided on the substrate, in a floating state.

6. The light emitting display device of claim 3, further comprising a power supply unit supplying power to at least one of the driving transistor, the cathode electrode, and the anode electrodes and connected with the main heat line.

7. The light emitting display device of claim 6, wherein the main heat line is functioned as a power supply line supplying a gate driver power to a gate driver provided in the non-display area, and
wherein the gate driver supplies gate signals to gate lines provided in the display area.

8. The light emitting display device of claim 3, further comprising a gate driver auxiliary electrode disposed on a same layer as gate driver electrodes constituting a gate driver provided in the non-display area and connected with the main heat line, and
wherein the gate driver auxiliary electrode is connected with the heat line.

9. The light emitting display device of claim 8, wherein the gate driver is supplied with a gate driver power through the gate driver auxiliary electrode.

10. The light emitting display device of claim 3, wherein the heat line includes at least two auxiliary heat lines electrically connected with each other, and
wherein the heat line hole includes auxiliary heat line holes corresponding to the auxiliary heat lines.

11. The light emitting display device of claim 10, wherein the auxiliary heat lines exposed through the auxiliary heat line holes are covered by the encapsulation layer.

12. The light emitting display device of claim 2, wherein the non-display area includes:
a first non-display area provided with a data driver supplying data voltages to data lines provided in the display area;
a second non-display area provided with a gate driver supplying gate signals to gate lines provided in the display area;
a third non-display area facing the first non-display area; and
a fourth non-display area facing the third non-display area,
wherein the second non-display area includes:
a first area adjacent to the display area;
a second area adjacent to the first area and provided with power supply lines supplying power to the gate driver;
a third area adjacent to the second area and provided with transistors constituting the gate driver; and
a fourth area provided with at least one clock line supplying at least one clock to the gate driver, and
wherein the heat line is provided in at least one of the first area and the third area.

13. The light emitting display device of claim 12, wherein the heat line is connected with a main heat line provided on a different layer from a layer where the heat line is provided,
wherein the heat line is provided in the third area, and
wherein the main heat line is provided in the first area or the second area.

14. The light emitting display device of claim 12, wherein the heat line is connected with a main heat line provided on a different layer from a layer where the heat line is provided,
wherein the heat line is provided in the first area and the third area, and
wherein the main heat line is provided in the second area.

15. The light emitting display device of claim 2, wherein the non-display area includes:
a first non-display area provided with a data driver supplying data voltages to data lines provided in the display area;
a second non-display area provided with a gate driver supplying gate signals to gate lines provided in the display area;
a third non-display area facing the first non-display area; and
a fourth non-display area facing the third non-display area, and
wherein the heat line is provided in at least one of the first non-display area, the second non-display area, the third non-display area, or the fourth non-display area.

16. A light emitting display device, comprising:
a substrate divided into a display area and a non-display area surrounding the display area;
a pixel driving circuit layer provided on the substrate and including a driving transistor;
a planarization layer covering the pixel driving circuit layer;
anode electrodes provided on the planarization layer in pixels;
banks disposed between the anode electrodes;
a light emitting layer disposed on the anode electrodes and the banks;
a cathode electrode disposed on the light emitting layer;
a capping layer covering the cathode electrode;
an encapsulation layer provided on side surfaces and an upper surface of the capping layer;
an encapsulation substrate attached to the capping layer through the encapsulation layer,
a foreign matter blocking area disposed where the light emitting layer and the cathode electrode are disconnected area in the non-display and surrounding the display area; and
an undercut area provided along the foreign matter blocking area,
wherein a side surface of the light emitting layer provided in the undercut area is covered by the cathode electrode.

17. The light emitting display device of claim 16, wherein the undercut area is provided along the foreign matter blocking area in the display area.

18. The light emitting display device of claim 16, wherein the undercut area is provided between the display area and the foreign matter blocking area.

19. The light emitting display device of claim 16, wherein the undercut area includes at least one of a pixel driving circuit layer, a planarization layer, a bank, an anode electrode and a light emitting layer is patterned.

20. The light emitting display device of claim 19, wherein the pixel driving circuit layer includes a protection layer, a sacrificial layer, and an interlayer insulating layer, and
wherein the undercut area includes at least one of the protection layer, the sacrificial layer and the interlayer insulating layer is patterned.

21. The light emitting display device of claim 20, wherein the sacrificial layer includes a gate line that is connected with a ground line or a low-potential power line.

22. A light emitting display device, comprising:
a substrate divided into a display area and a non-display area surrounding the display area;
a pixel driving circuit layer provided on the substrate and including a driving transistor;
a planarization layer covering the pixel driving circuit layer;
anode electrodes provided on the planarization layer and respectively provided in pixels;
a light emitting layer disposed on the anode electrodes;
a cathode electrode disposed on the light emitting layer;
a foreign matter blocking area disposed in the non-display area, surrounding the display area and disposed in an area where the light emitting layer and the cathode electrode are disconnected; and
a pixel undercut area disposed between the pixels and disposed along the foreign matter blocking area.

23. The light emitting display device of claim 22, wherein the pixel undercut area is disposed where the planarization layer is disconnected and has an undercut structure in which the anode electrode is disposed protruding further outward than an end of the planarization layer.

24. The light emitting display device of claim 23, wherein the light emitting layer and the cathode electrode are disposed further inward than an end of the anode electrode.

25. The light emitting display device of claim 23, wherein the light emitting layer and the cathode electrode are disposed on the pixel driving circuit layer in an area where the planarization layer is disconnected, and
wherein the light emitting layer and the cathode electrode do not overlap with an end of the anode electrode.

26. The light emitting display device of claim 22, further comprising:
a capping layer covering the cathode electrode;
an encapsulation layer provided on side surfaces and an upper surface of the capping layer; and
an encapsulation substrate attached on the capping layer through the encapsulation layer.

27. The light emitting display device of claim 22, further comprising a heat line provided in the foreign matter blocking area and a heat line hole provided in the light emitting layer provided in the foreign matter blocking area.

28. The light emitting display device of claim 27, wherein the heat line is connected with a main heat line provided on a different layer from a layer where the heat line is provided.

29. The light emitting display device of claim 28, wherein the anode electrode is connected with the main heat line.

30. The light emitting display device of claim 28, further comprising a gate driver auxiliary electrode formed on a same layer as gate driver electrodes constituting a gate driver provided in the non-display area and connected with the main heat line, and
wherein the gate driver auxiliary electrode is connected with the heat line.
